(19) United States
(12) Patent Application Publication
(10) Pub. No.: US 2026/0040608 A1
(43) Pub. Date: Feb. 5, 2026

(54) LDMOS WITH NANOSHEET CHANNEL AND METHODS FOR MANUFACTURING THE SAME

(71) Applicant: TEXAS INSTRUMENTS INCORPORATED, Dallas, TX (US)

(72) Inventors: Daniel Pham, Celina, TX (US); Steven Huynh, Melissa, TX (US); Henry L Edwards, Garland, TX (US)

(21) Appl. No.: 18/790,257

(22) Filed: Jul. 31, 2024

(51) Int. Cl. H01L 29/78; H01L 29/06; H01L 29/66; H01L 29/775; H01L 29/786

(52) U.S. Cl. CPC H10D 30/65; H10D 30/014; H10D 30/0285; H10D 30/43; H10D 30/6757; H10D 62/115; H10D 62/121

(57) ABSTRACT

Disclosed herein is a method including receiving a semiconductor substrate having a first semiconductor material layer and a different second semiconductor material layer disposed on the first semiconductor material layer, forming a drift region overlapping the first semiconductor material layer, the drift region doped to a first conductivity type, forming a gate electrode layer over the field relief insulator, removing a first portion of the second semiconductor material layer to form a trench that exposes a first portion of the first semiconductor material layer, removing the exposed first portion of the first semiconductor material layer to extend the trench under the gate electrode layer toward the drift region, wherein a second portion of the second semiconductor material layer is exposed in the extended trench, and forming a dielectric isolation structure in the extended trench, the dielectric isolation structure touching the second portion of the second semiconductor material layer.

### FIELD

The present disclosure generally relates to field effect transistors.

### BACKGROUND

Semiconductor devices, such as silicon devices, have a wide range of applications. For example, field effect transistors (FETs) and laterally diffused metal oxide semiconductor (LDMOS) devices are used in many applications. While current methods of manufacture for semiconductor devices have been adequate, issues arise as the size of the semiconductor devices continues to shrink.

### SUMMARY

Disclosed herein is a method including receiving a semiconductor substrate having a first semiconductor material layer and a different second semiconductor material layer disposed on the first semiconductor material layer. The method further includes forming a drift region overlapping the first semiconductor material layer, the drift region doped to a first conductivity type. The method further includes forming a field relief insulator over the drift region, forming a gate electrode layer over the field relief insulator, and removing a first portion of the second semiconductor material layer to form a trench that exposes a first portion of the first semiconductor material layer. The method further includes removing the exposed first portion of the first semiconductor material layer to extend the trench under the gate electrode layer toward the drift region, where a second portion of the second semiconductor material layer is exposed in the extended trench. The method further includes forming a dielectric isolation structure in the extended trench, the dielectric isolation structure touching the second portion of the second semiconductor material layer.

Also disclosed herein is a method including forming a first semiconductor material layer on a substrate, forming a second semiconductor material layer on the first semiconductor material layer, the second semiconductor material layer having a different material composition than the first semiconductor material layer, and forming a gate structure over the second semiconductor material layer. The method further includes forming a first trench through the first semiconductor material layer and the second semiconductor material layer adjacent the gate structure to expose a first portion of the substrate, removing the first portion of the substrate through the first trench to expose a first portion of the first semiconductor material layer, and removing the exposed first portion of the first semiconductor material layer, thereby exposing a first portion of the second semiconductor material layer and a second portion of the first semiconductor material layer. The method further includes forming a dielectric isolation structure directly on the first portion of the second semiconductor material layer and the second portion of the first semiconductor material layer.

Also disclosed herein is a device including a first semiconductor material layer, disposed over a substrate, a second semiconductor material layer disposed on the first semiconductor material layer, and a drift region extending through the first semiconductor material layer into the substrate, the drift region doped to a first conductivity type. The device further includes a body region disposed in the second semiconductor material layer and the substrate, the body region doped to a second conductivity type that is opposite the first conductivity type, a source region extending into the body region and doped to the first conductivity type, and a drain region extending into the drift region and doped to the first conductivity type. The device further includes a gate structure including a gate electrode layer spaced apart from the second semiconductor layer by a gate dielectric layer and a dielectric isolation structure under the body region and having a first portion extending into the substrate and a second portion extending beyond an edge of the first portion toward the drain region between the gate structure and the substrate and abutting the first semiconductor material layer.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flowchart for a method of forming a semiconductor device, in accordance with various examples.

FIGS. 2A, 2B, 2C, 2D, 2E, 2F, and 2G illustrate cross-section views of a semiconductor device, in accordance with the process of FIG. 1 and the various examples associated therewith.

FIG. 3 illustrates a flowchart for a method of forming a semiconductor device, in accordance with various examples.

FIGS. 4A, 4B, 4C, 4D, 4E, 4F, 4G, 4H, 4I, 4J, 4K, 4L, 4M, 4N, 4O, 4P, 4Q, 4R, 4S, 4T, 4U, 4V, 4W, 4X, and 4Y illustrate cross-section views of a semiconductor device, in accordance with the process disclosed in FIG. 3 and the various examples associated therewith.

FIG. 5 illustrates a cross-section view of a semiconductor device, in accordance with various examples.

FIG. 6 illustrates a cross-section view of a semiconductor device, in accordance with various examples.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to enable a person of skill in the art to practice the disclosure. It is understood that connecting lines shown in the various drawings are intended to represent exemple functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit those of skill in the art to practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted by one of skill in the art and may include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to provide examples and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for case of discussion herein and are not intended to limit the orientation of the various components, systems, apparatuses, devices, or other features. It is therefore understood and appreciated that one skilled in the art would be able to use the spatially relative terms to practice this disclosure in different orientations while remaining within the scope of the present disclosure.

Current laterally diffused metal-oxide-semiconductor (LDMOS) field-effect transistors (FETs) may experience short channel effects as they are scaled down. As the channel region of the LDMOS is scaled down the current leak through the channel during use tends to increase. Other short channel effects may include mobility degradation, drain punch through, and/or threshold voltage roll-off, among others. These may be counteracted by increasing the channel doping concentration. However, a higher dopant concentration in the channel region tends to result in reduced channel mobility.

Disclosed herein are, inter alia, methods for forming a thin, or nanosheet, channel region in a semiconductor device (e.g., LDMOS FET). The nanosheet channel region is bounded by a top surface of a semiconductor layer and an isolation structure that extends into the semiconductor layer. The isolation structure disclosed herein has a lateral length extending in the direction of the transistor's channel length and a vertical depth extending towards the substrate. In various examples, the lateral length of the isolation structure may be selected to alter the gate control of the device with little to no change in the drain-source resistance. In various examples, the vertical depth of the isolation structure may vary depending on the application usage of the transistor (e.g. voltage applied to drain side of the semiconductor device). In various examples, the isolation structure may extend deeper into the substrate when the transistor is a higher voltage transistor (e.g. applied voltage to the drain is higher) and may be made shallower when the transistor is a lower voltage transistor (e.g. the supplied voltage to the drain is lower). While implementations of the nanosheet channel region are expected to improve gate control of the semiconductor device by reducing the short channel effect, no particular result is a requirement unless explicitly recited in a claim.

The methods and devices disclosed herein form a thin silicon channel region that is partially defined by the isolation structure disposed under the thin silicon channel region. Using the methods disclosed herein the semiconductor device is able to have, in various examples, a thin channel region (such as a nanosheet film) having a lower doping concentration than would otherwise be used in analogous scaled down conventional devices, such as an LDMOS FET. The relatively reduced doping concentration provides the benefits of increased channel mobility and/or reduced channel resistivity. Additionally, in various examples, a thickness of the thin channel region may be determined by whether the transistor is intended to operate with a partially depleted channel region and/or a fully depleted channel region.

As disclosed herein, the channel of a transistor, such as an LDMOS FET, may be a thin silicon channel region such as a nanosheet film of silicon. By nanosheet, it is meant that the thickness of the silicon channel region between the surface of the silicon substrate and the isolation structure is less than one micron, and may be as small as a few hundred nanometers, or less. The isolation structure may be formed under the channel region and, in various examples, be extended deep into the substrate to a buried layer. The methods disclosed herein include, in various examples, forming a first semiconductor material layer on a substrate and forming a second semiconductor material layer on the first semiconductor material layer. In various examples, the substrate includes silicon, the first semiconductor material layer includes silicon-germanium, and the second semiconductor material layer includes substantially pure silicon. In various examples, a first recess may be formed through the second material layer, the first material layer, and into the substrate. In various examples, one or more dielectric spacers may be formed on sidewalls of the second semiconductor material layer and/or the first semiconductor material layer exposed by the first recess. In various examples, a first selective etching process may be performed to extend the first recess under the one or more dielectric spacers, including under the first semiconductor material layer. In various examples, a second selective etching process may be performed to form a second recess, such as a lateral recess, through the extended first recess by removing a portion of the first semiconductor material layer. In various examples, one or more dielectric materials are formed in the first recess, the extended first recess, and the second recess. The one or more dielectric materials are, in various examples, formed to create an isolation structure, including a portion extending under the second semiconductor layer. The portion of the isolation structure extending under the second semiconductor layer at least partially defines a nanosheet channel region that includes the second semiconductor material layer.

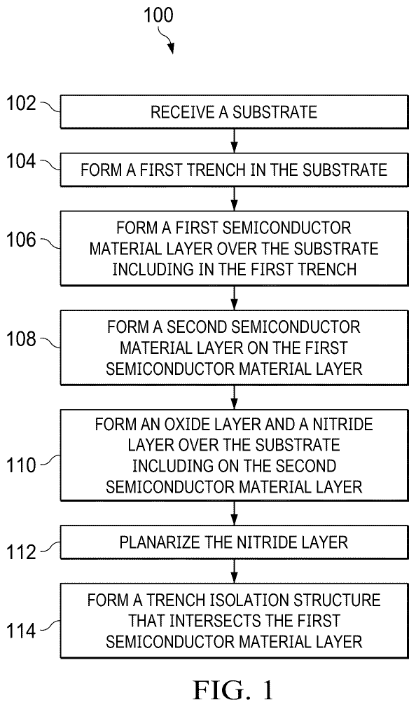

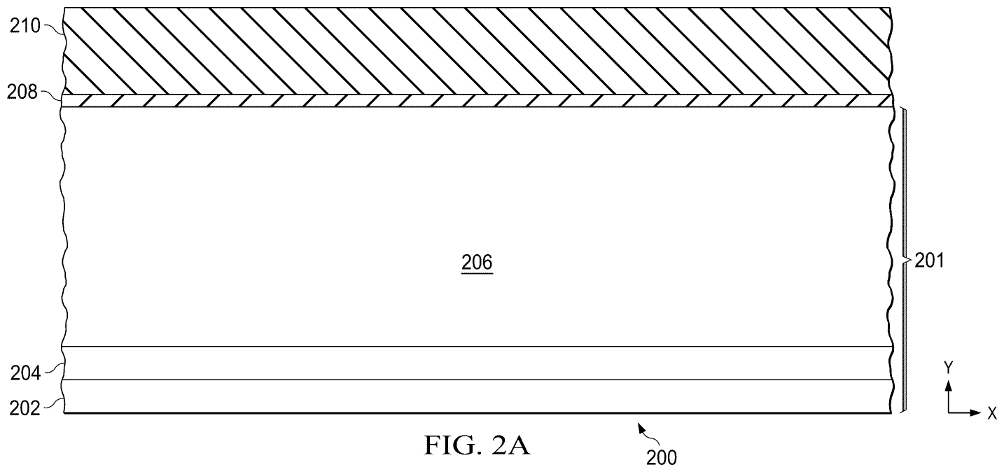

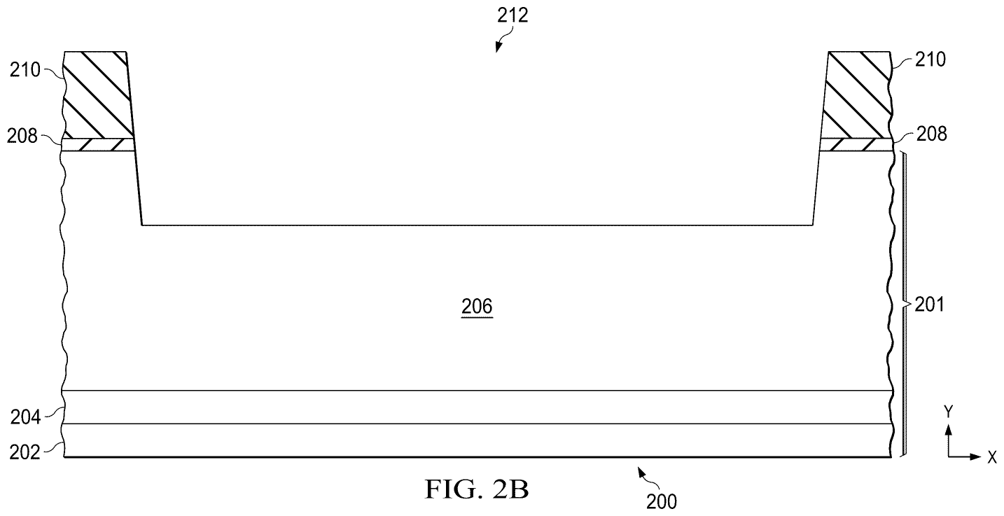

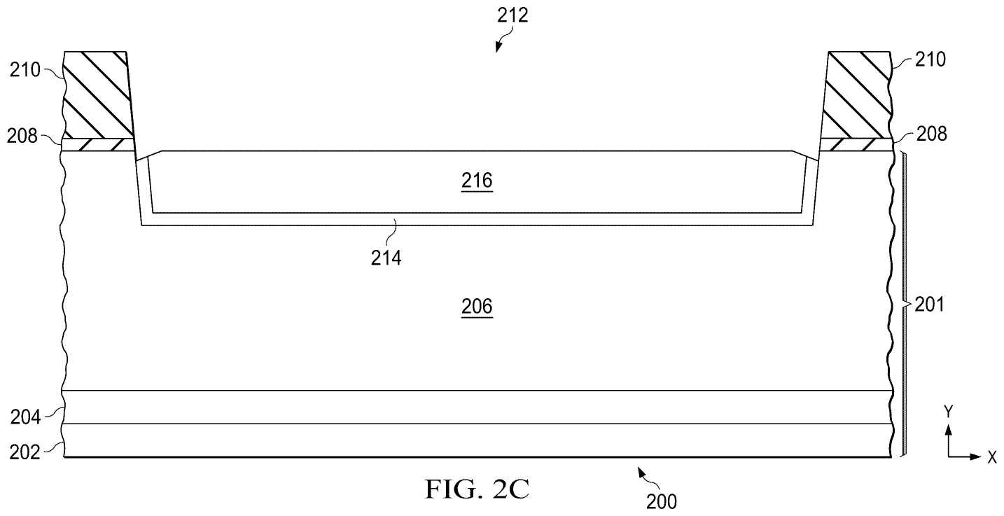

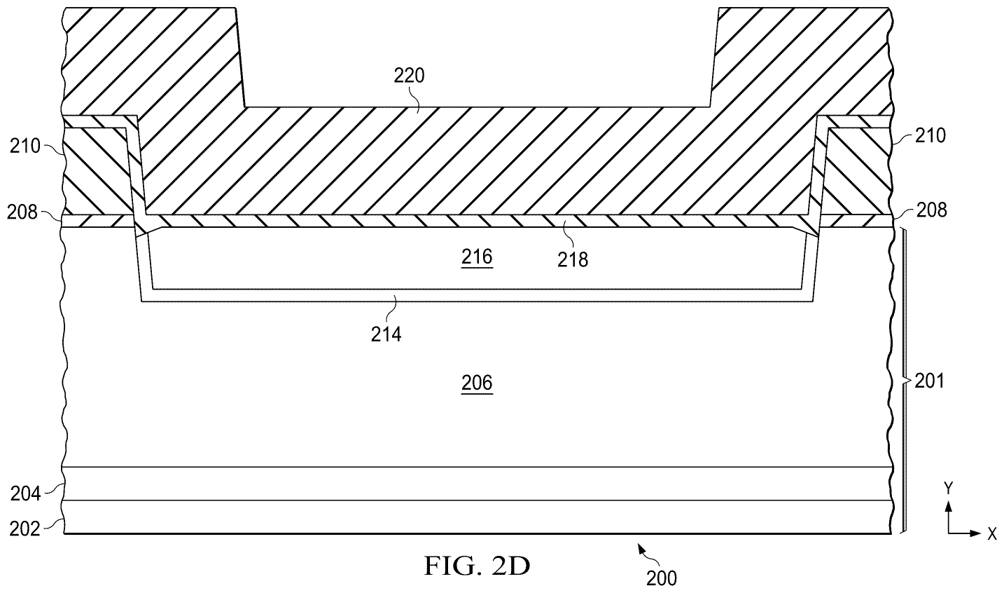

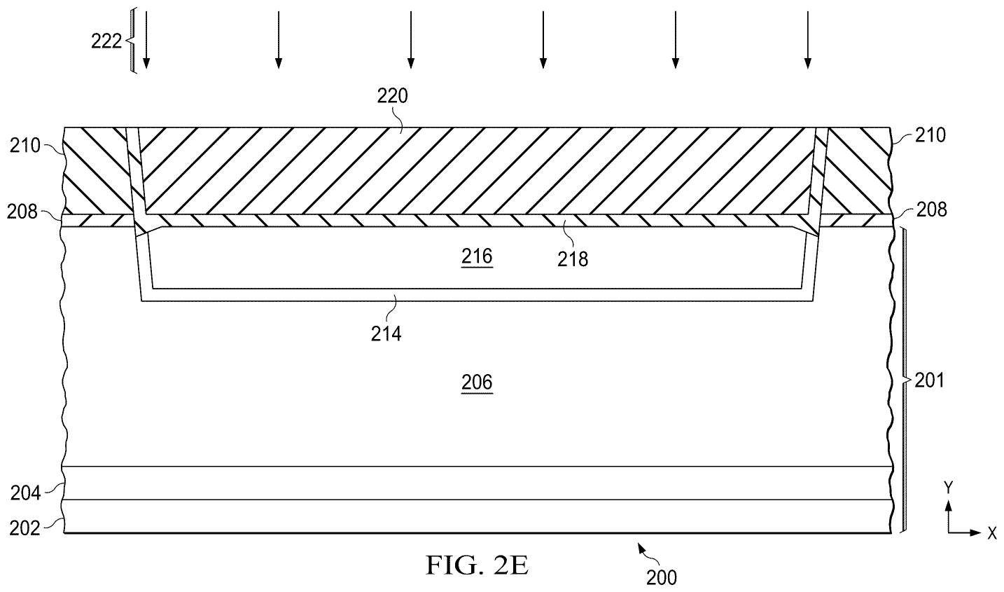

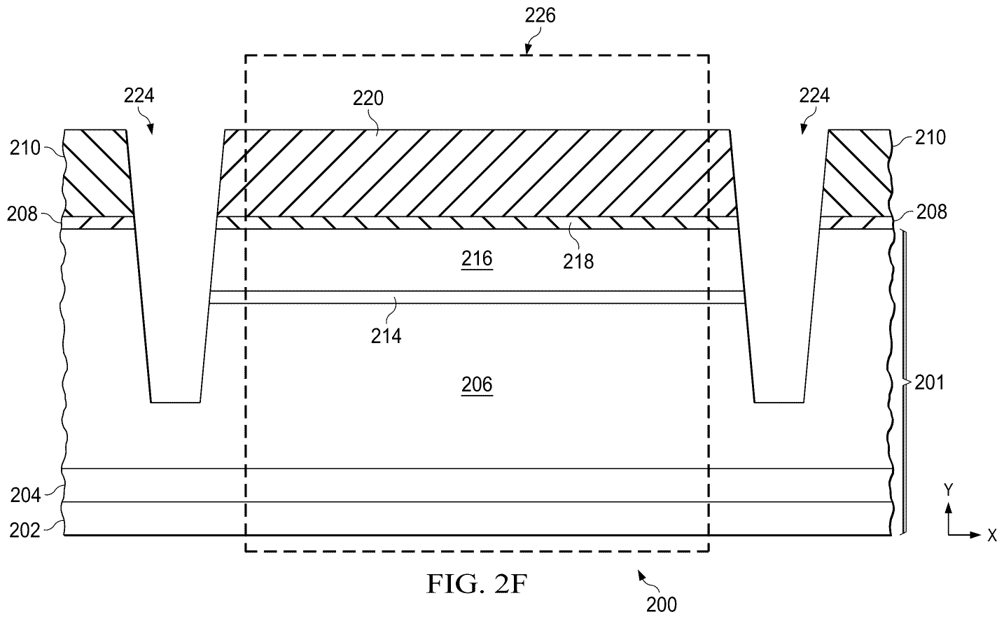

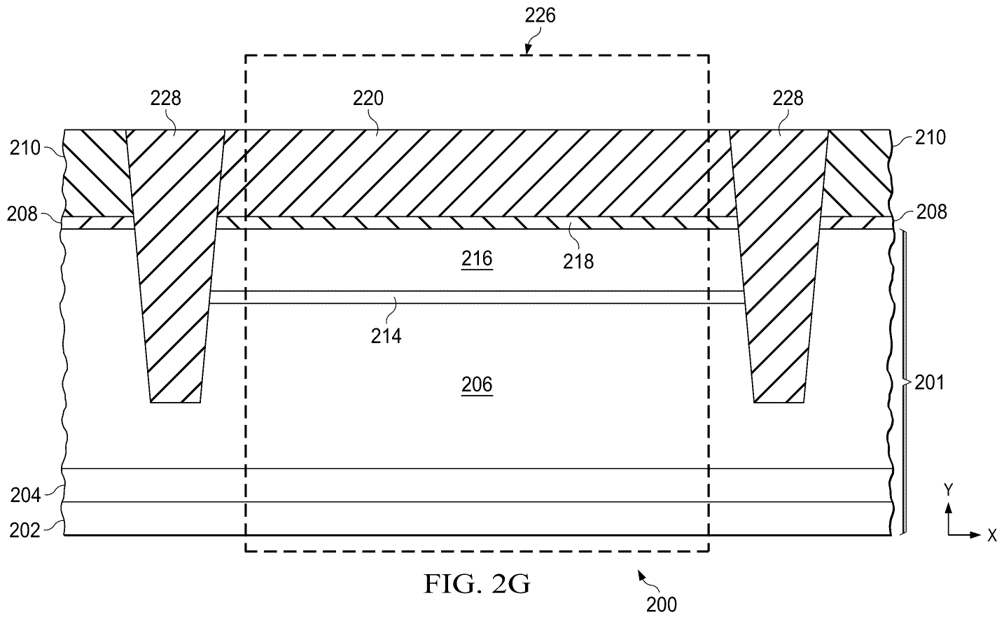

Referring now to FIG. 1, a flow diagram of a method 100 for forming an isolation structure in a substrate adjacent a region for a field-effect-transistor (FET) is illustrated, in accordance with various examples of the present disclosure. In various examples, method 100 may be used to form an isolation structure in a substrate adjacent a region for a laterally diffused metal-oxide-semiconductor (LDMOS) FET. Additional processes can be provided before, during, and after method 100. As discussed below, method 100 is described with reference to FIGS. 2A-2G.

In that regard, FIGS. 2A-2G are diagrammatic cross-sectional views of a device 200 at various stages of fabrication (such as those associated with method 100 of FIG. 1) according to various aspects of the present disclosure. In various examples, device 200 may be a laterally diffused metal-oxide-semiconductor (LDMOS) field-effect-transistor (FET). Additional features can be added to device 200, and some features described below can be replaced, modified, or eliminated in other examples of device 200.

At step 102 of FIG. 1, a substrate is received. As shown in FIG. 2A, device 200 includes a substrate 201 with a first doped semiconductor layer 202 that may be p-type (e.g. a first p-type semiconductor layer), a buried layer 204 (e.g. a buried layer), and a second doped semiconductor layer 206 that may be p-type (e.g. a second p-type semiconductor layer). In some examples, not shown, substrate 201 may include an insulating layer, such as silicon-on-insulator (SOI) substrate. In some such examples first doped semiconductor layer 202 may be omitted. Device 200 further includes a first oxide layer 208 formed on substrate 201 and a first nitride layer 210 formed on first oxide layer 208. In various examples, first doped semiconductor layer 202 and second doped semiconductor layer 206 may be doped with one or more p-type dopants such a boron, and buried layer 204 may be doped with one or more n-type dopants such as arsenic, phosphorous and antimony. In various other examples, first doped semiconductor layer 202, buried layer 204 and second doped semiconductor layer 206 may be oppositely doped. For example, first doped semiconductor layer 202 may be an n-type semiconductor layer, buried layer 204 may be a p-type layer, and second doped semiconductor layer 206 may be an n-type semiconductor layer. Accordingly, the description provided herein is applicable to n-channel LDMOS FETs and p-channel LDMOS FETs with appropriate changes to the polarities of the dopants. Polarity of the dopants may also be referred to as conductivity type herein.

Substrate 201 may be formed by a variety of methods. In various examples, first doped semiconductor layer 202 may be formed on a wafer, buried layer 204 may be formed on first doped semiconductor layer 202, and second doped semiconductor layer 206 may be formed on buried layer 204. First doped semiconductor layer 202 may include silicon and be doped with p-type dopants such as boron. In various examples, substrate 201 may be formed by starting with first doped semiconductor layer 202 and forming buried layer 204 by ion implanting n-type dopants such as antimony, phosphorus, or arsenic at a dose of about 1×10¹⁵ cm⁻² to about 1×10¹⁶ cm⁻². After the ion implanting, a thermal drive process heats the wafer to activate and diffuse the implanted n-type dopants.

Second doped semiconductor layer 206 may be formed on the wafer by an epitaxial process with in-situ p-type doping. Second doped semiconductor layer 206 may include silicon and be doped with p-type dopants such as boron. An average bulk resistivity of second doped semiconductor layer 206 may be, for example, 1 ohm-cm to 10 ohm-cm. In various examples, second doped semiconductor layer 206 may be formed by implanting boron at an energy of about 2 mega-electron volts (MeV) to about 3 MeV.

First oxide layer 208 is formed on a top surface (e.g., in the positive y-direction) of substrate 201. As shown, first oxide layer 208 is formed on second doped semiconductor layer 206. In various examples, first oxide layer 208 may include, for example, silicon oxide. As one skilled in the art would understand, the use of the term silicon oxide throughout this disclosure includes materials such as silicon monoxide (SiO) and/or silicon dioxide (SiO₂) and/or a non-stoichiometric mixture of the two. First oxide layer 208 may be formed by thermal oxidation or by any of several chemical vapor deposition (CVD) processes.

First nitride layer 210 is formed on first oxide layer 208. First nitride layer 210 may include, for example, silicon nitride and/or silicon oxynitride. First nitride layer 210 may be formed by a low-pressure chemical vapor deposition (LPCVD) process using dichlorosilane and ammonia. Alternatively, first nitride layer 210 may be formed by decomposition of bis(tertiary-butyl-amino) silane (BTBAS). Other processes to form first nitride layer 210 are possible.

At step 104 of FIG. 1, a first trench is formed in the substrate. As shown in FIG. 2B, a first trench 212 is formed through first nitride layer 210 and first oxide layer 208 and into substrate 201, and more specifically, into second doped semiconductor layer 206. First trench 212 exposes a top surface (e.g., in the positive y-direction) of second doped semiconductor layer 206, sidewalls of second doped semiconductor layer 206, sidewalls of first oxide layer 208, and sidewalls of first nitride layer 210. In various examples, one or more etching processes may be performed to remove a portion of first nitride layer 210, a portion of first oxide layer 208, and a portion of second doped semiconductor layer 206 to form first trench 212. In various examples, the one or more etching processes may include forming an etch mask on device 200 before performing each etching process. The etch mask may, in various examples, include photoresist formed by a photolithography process. The etch mask may, in various examples, also include a hard mask material such as amorphous carbon and may further include an anti-reflection layer such as an organic bottom anti-reflection coat (BARC).

At steps 106 and 108 of FIG. 1, a first semiconductor material layer is formed over the substrate including in the first trench and a second semiconductor material layer is formed on the first semiconductor material layer. As shown in FIG. 2C, a first semiconductor material layer 214 and a second semiconductor material layer 216 are formed on device 200. First semiconductor material layer 214 is formed in first trench 212 including on the top surface and sidewalls of second doped semiconductor layer 206. In various examples, first semiconductor material layer 214 may be silicon-germanium (SiGe). In various examples, second semiconductor material layer 216 may be silicon (Si). That is, in various examples first semiconductor material layer 214 has a different material composition than second semiconductor material layer 216. In various examples in which first semiconductor material layer 214 is SiGe, first semiconductor material layer 214 has a Ge concentration of about 10% to about 40%, and more specifically, about 15% to about 35%. In various examples, first semiconductor material layer 214 has a thickness of about 50 nm to about 500 nm, and more specifically, about 100 nm to about 400 nm. In various examples, the Ge concentration and the thickness of first semiconductor material layer 214 combined causes compressive strain of first semiconductor material layer 214.

Additionally, first semiconductor material layer 214 may have a different material composition than second doped semiconductor layer 206 of substrate 201. That is, in some examples where second doped semiconductor layer 206 is a Si layer, first semiconductor material layer 214 is a SiGe layer and second semiconductor material layer 216 is a Si layer. In various examples, first semiconductor material layer 214 may additionally be formed on sidewalls of first oxide layer 208 and/or sidewalls of first nitride layer 210. First semiconductor material layer 214 may then be recessed to expose a top surface (e.g., in the positive y-direction) and sidewalls (e.g., in the positive and negative x-directions) of first semiconductor material layer 214. In various examples, first semiconductor material layer 214 may be formed by a selective epitaxial process.

As shown in FIG. 2C, second semiconductor material layer 216 is formed in first trench 212 and on first semiconductor material layer 214. In various examples, second semiconductor material layer 216 may be Si. In various examples, second semiconductor material layer 216 may be SiGe. Second semiconductor material layer 216 may have a different material composition than first semiconductor material layer 214. In various examples, second semiconductor material layer 216 may be formed of the same type of material as second doped semiconductor layer 206 of substrate 201. That is, in some examples in which first semiconductor material layer 214 is Si then second semiconductor material layer 216 is SiGe, and in some examples in which first semiconductor material layer 214 is SiGe then second semiconductor material layer 216 is Si. In various examples, second semiconductor material layer 216 may be formed by a selective epitaxial process (e.g., first semiconductor material layer 214 may grow on Si surfaces). In various examples in which second semiconductor material layer 216 is Si, second semiconductor material layer 216 has a thickness of about 5 nm to about 500 nm, and more specifically, about 10 nm to about 200 nm.

At step 110 of FIG. 1, an oxide layer and a nitride layer are formed over the substrate including on the second semiconductor material layer. As shown in FIG. 2D, a second oxide layer 218 and a second nitride layer 220 are formed on device 200. Second oxide layer 218 is formed on second semiconductor material layer 216 and first nitride layer 210 and, in various examples, on first semiconductor material layer 214 and first oxide layer 208. Second oxide layer 218 may be formed using similar processes as described about with respect to first oxide layer 208. Second nitride layer 220 is formed on second oxide layer 218. Second nitride layer 220 may be formed using similar processes as those described above with respect to first nitride layer 210.

At step 112 of FIG. 1, a planarization is performed to planarize the nitride layer. As shown in FIG. 2E, a planarization process 222 is performed on device 200 to make a top surface (e.g., in the positive y-direction) of device 200 (e.g., first nitride layer 210 and second nitride layer 220) planar. In various examples, planarization process 222 may be a chemical mechanical polishing (CMP) process. The CMP process removes portions of second nitride layer 220, second oxide layer 218, and first nitride layer 210 to planarize the top surface of device 200.

At step 114 of FIG. 1, a trench isolation structure that intersects the first semiconductor material layer is formed. As shown in FIG. 2F, second trenches 224 are formed in device 200 adjacent edges of a region 226 that is delineated by a dash line. In various examples, region 226 indicates where an LDMOS FET, or other FET, will be formed or has already been formed as part of device 200. Second trenches 224 are formed through second nitride layer 220, second oxide layer 218, first nitride layer 210, and first oxide layer 208 and into substrate 201. In various examples, second trenches 224 may be formed through second doped semiconductor layer 206 and buried layer 204 and into first doped semiconductor layer 202. Second trenches 224 expose a top surface (e.g., in the positive y-direction) of first doped semiconductor layer 202 and sidewalls of buried layer 204, second doped semiconductor layer 206, second oxide layer 218, first nitride layer 210, and/or second nitride layer 220.

In various examples, one or more etching processes may be performed to remove a portion of second nitride layer 220, second oxide layer 218, first nitride layer 210, first oxide layer 208, and substrate 201 to form second trenches 224. In various examples, the one or more etching processes may include forming an etch mask on device 200 before performing each etching process. The etch mask may, in various examples, include photoresist formed by a photolithography process. The etch mask may, in various examples, also include a hard mask material such as amorphous carbon and may further include an anti-reflection layer such as an organic bottom anti-reflection coat (BARC).

FIG. 2G shows second trenches 224 subsequently filled with a dielectric material to form a dielectric isolation structure 228. In some examples, dielectric isolation structure 228 is a shallow trench isolation (STI) structure. It understood that dielectric isolation structure 228 may be formed of one or more layers of dielectric material. For example, dielectric isolation structure 228 may include a dielectric liner layer and a bulk dielectric material. In some examples, the dielectric liner layer and the bulk dielectric material may have different material compositions. Additionally, in various examples, it is understood that a planarization process may be applied to the dielectric material to form dielectric isolation structure.

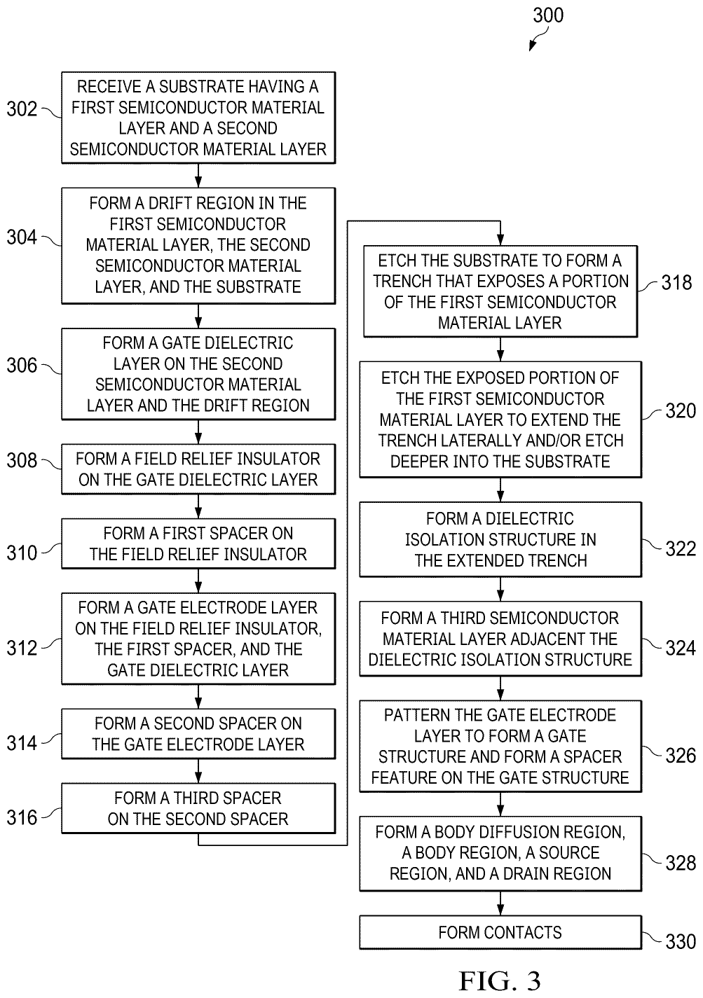

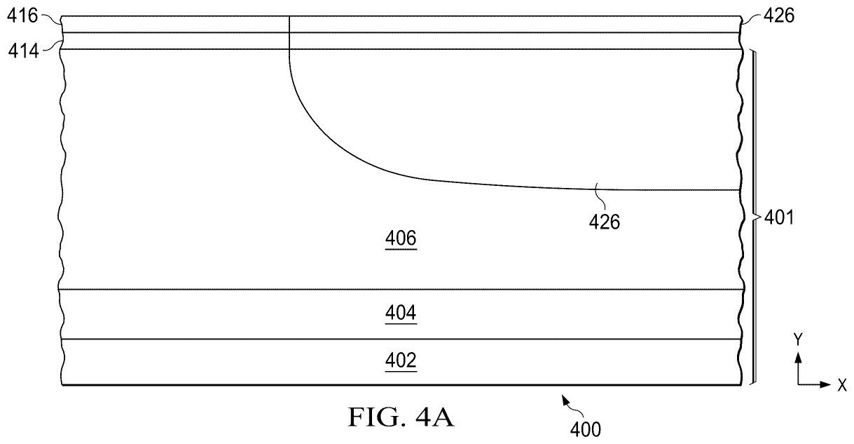

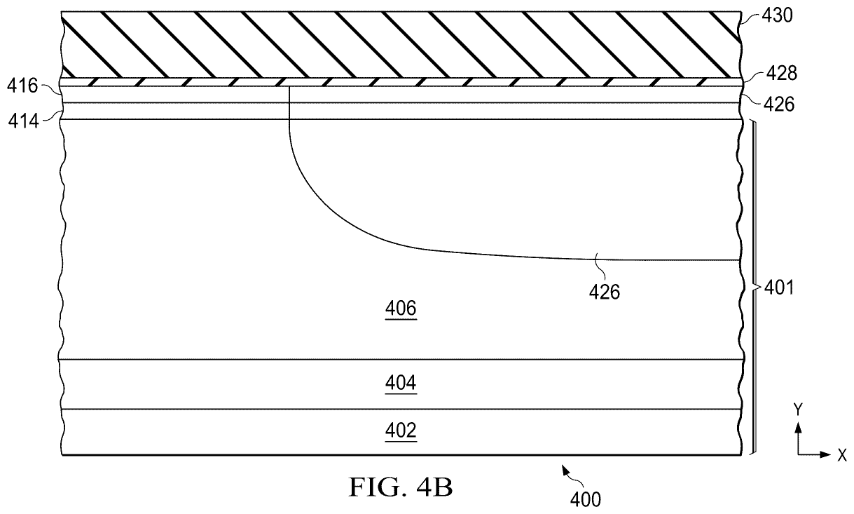

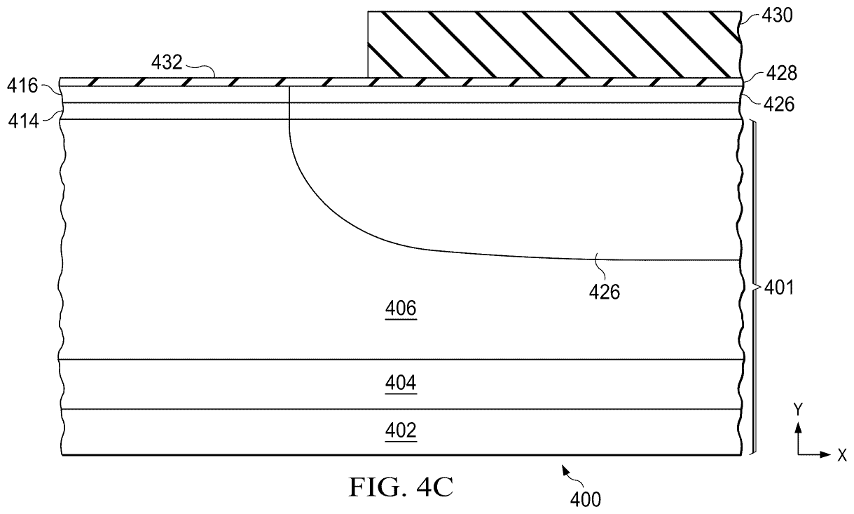

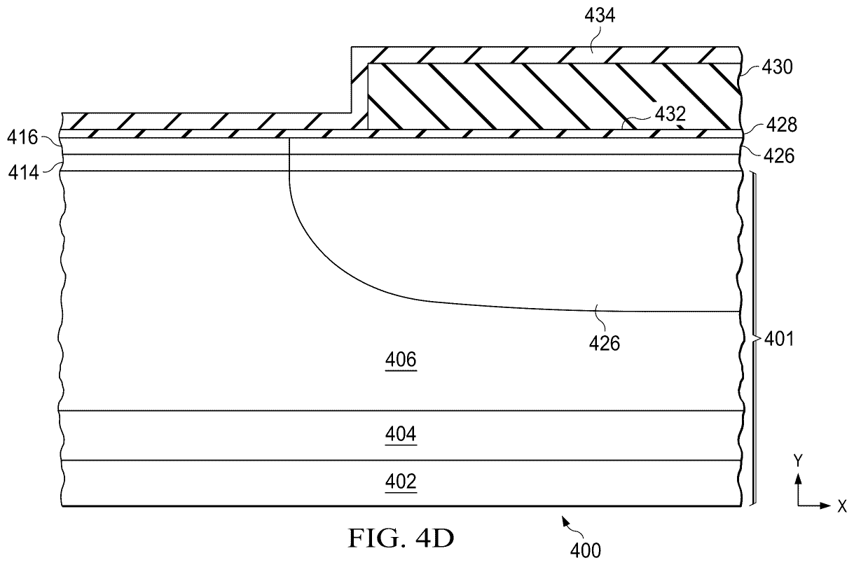

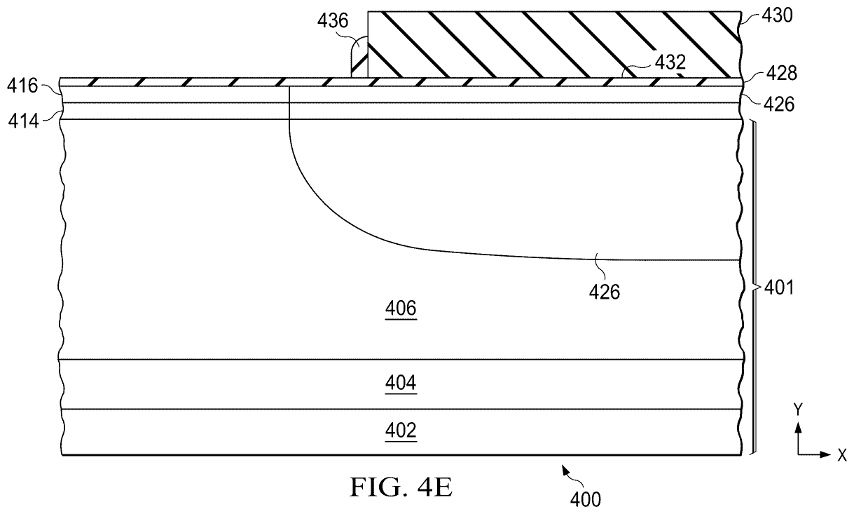

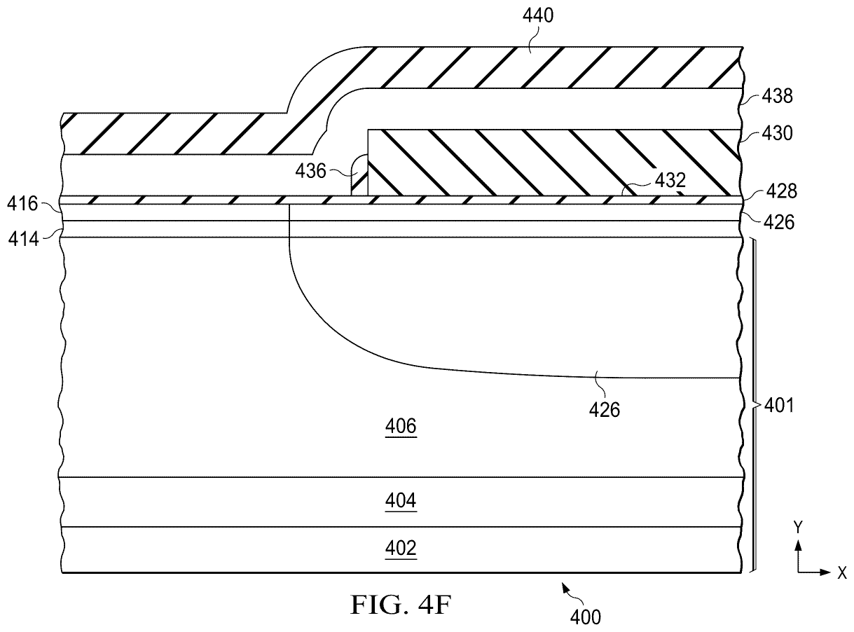

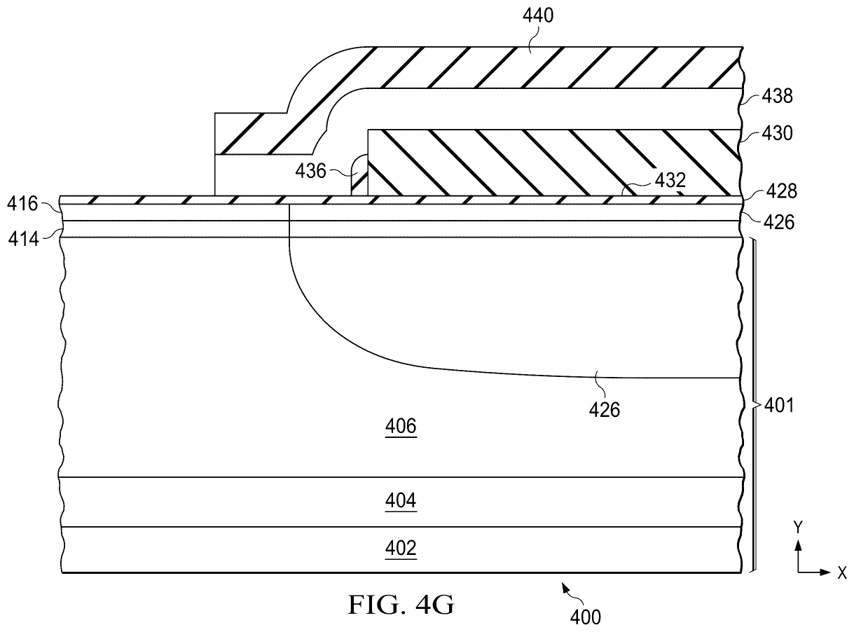

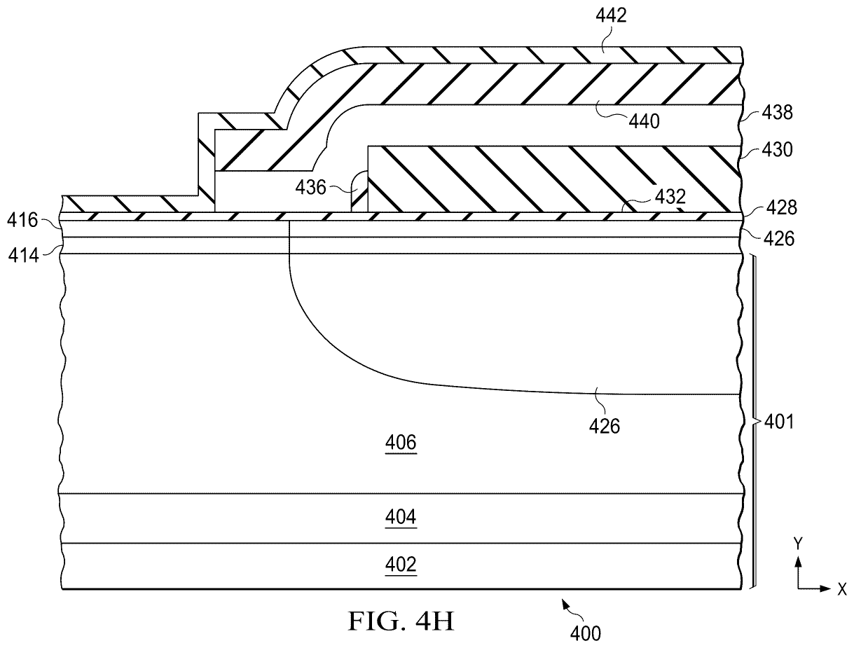

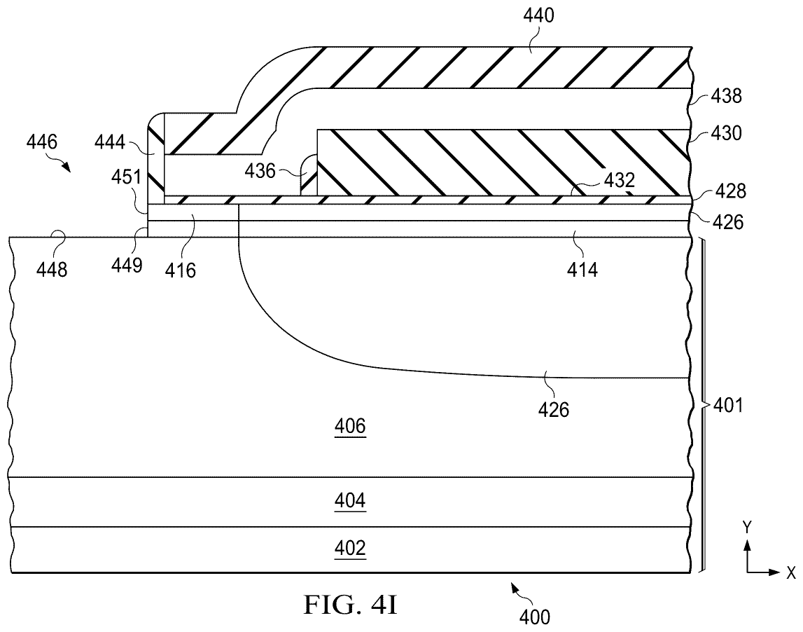

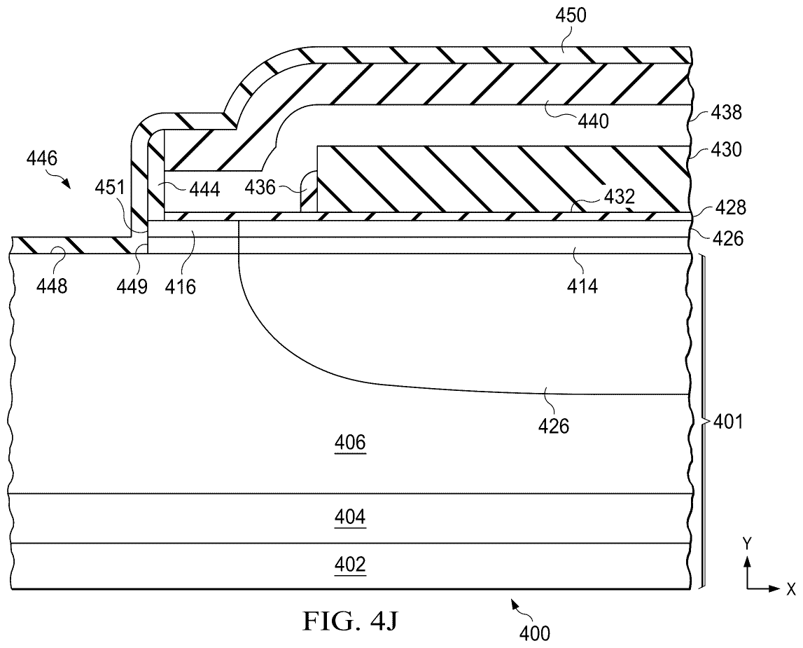

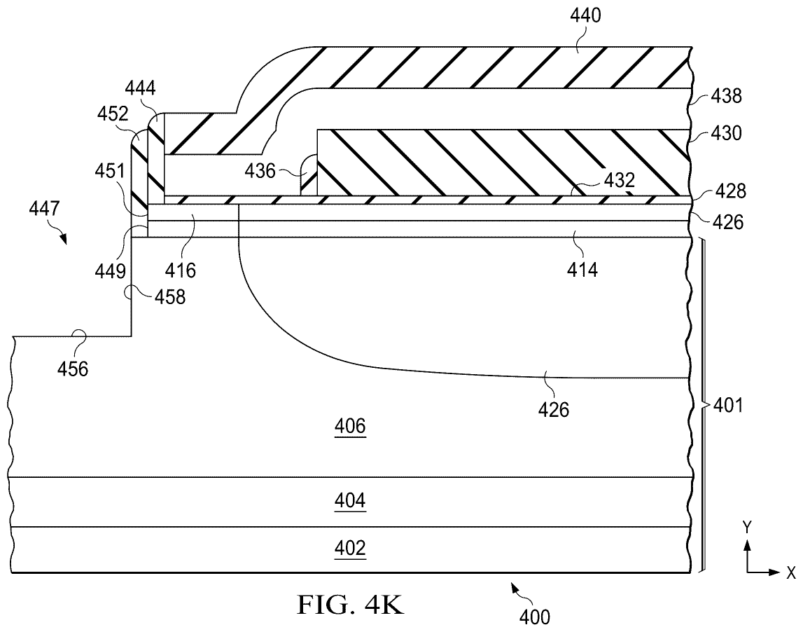

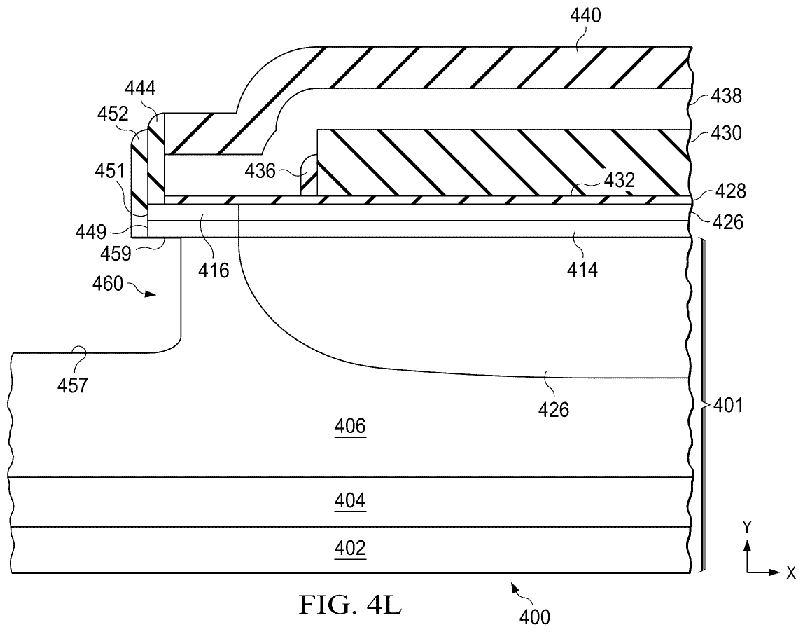

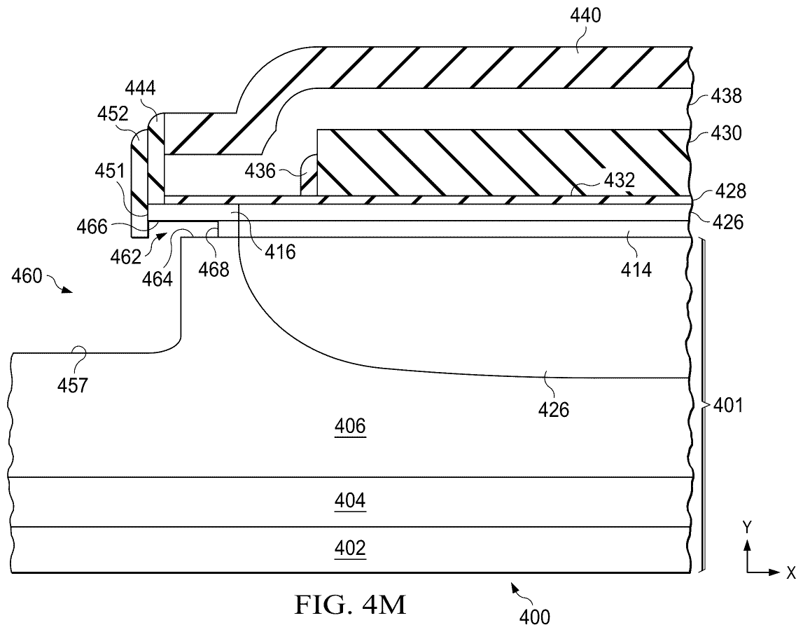

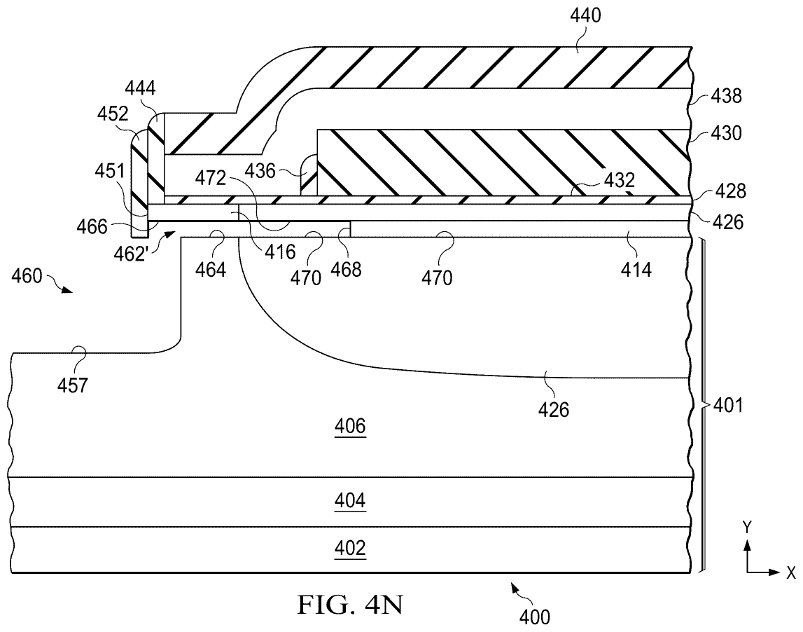

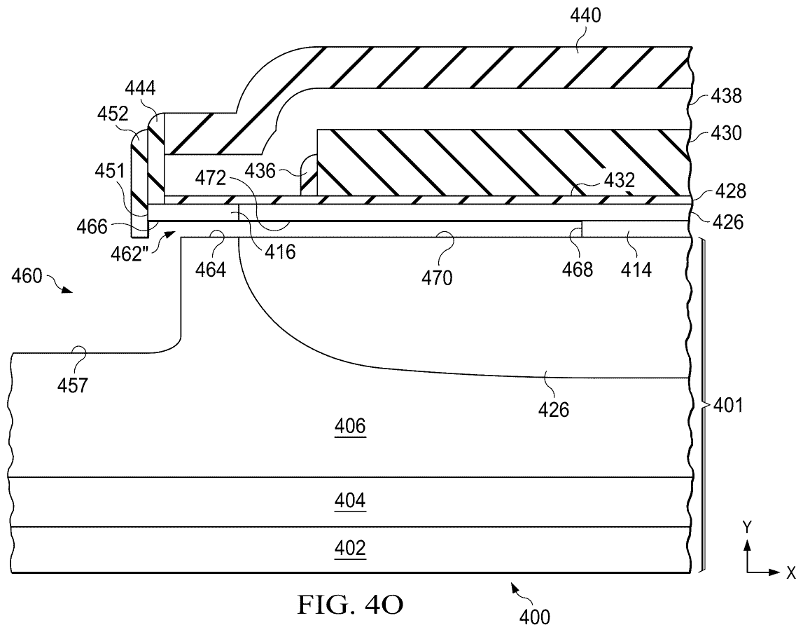

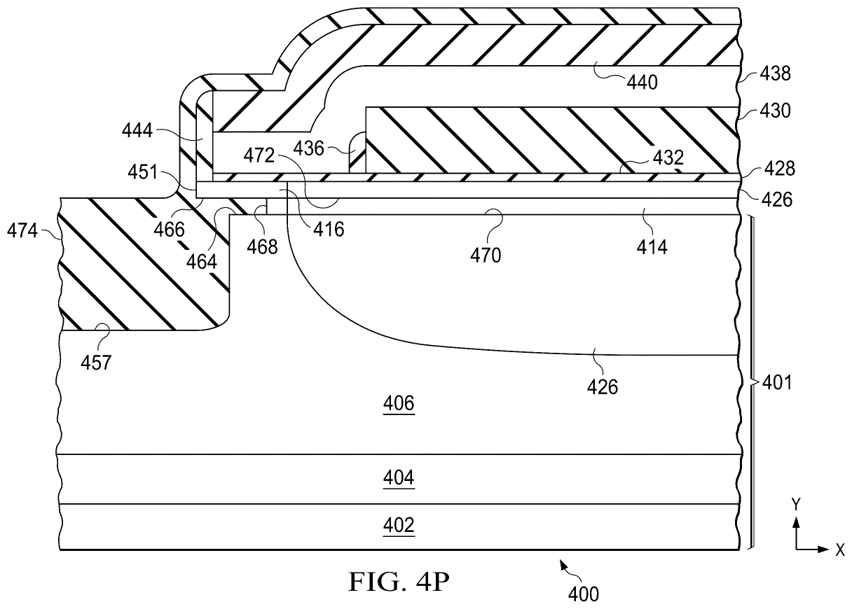

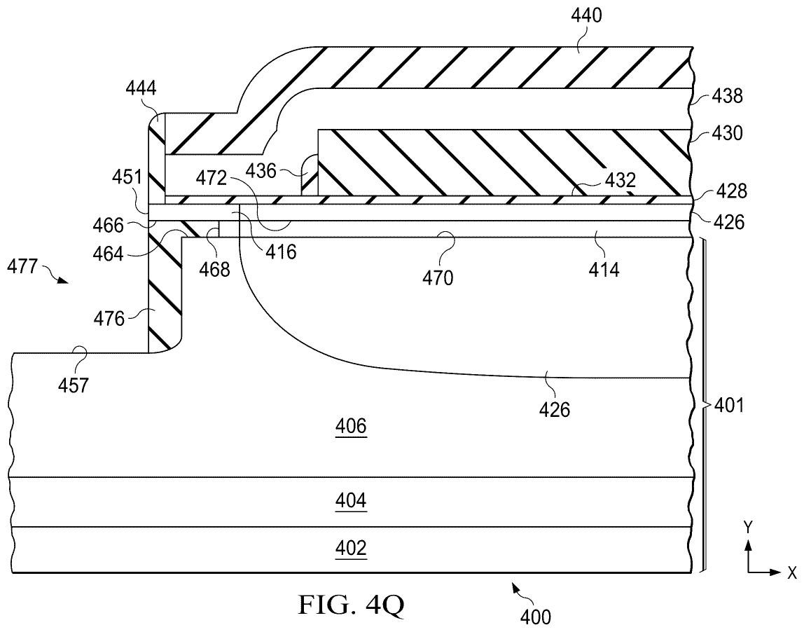

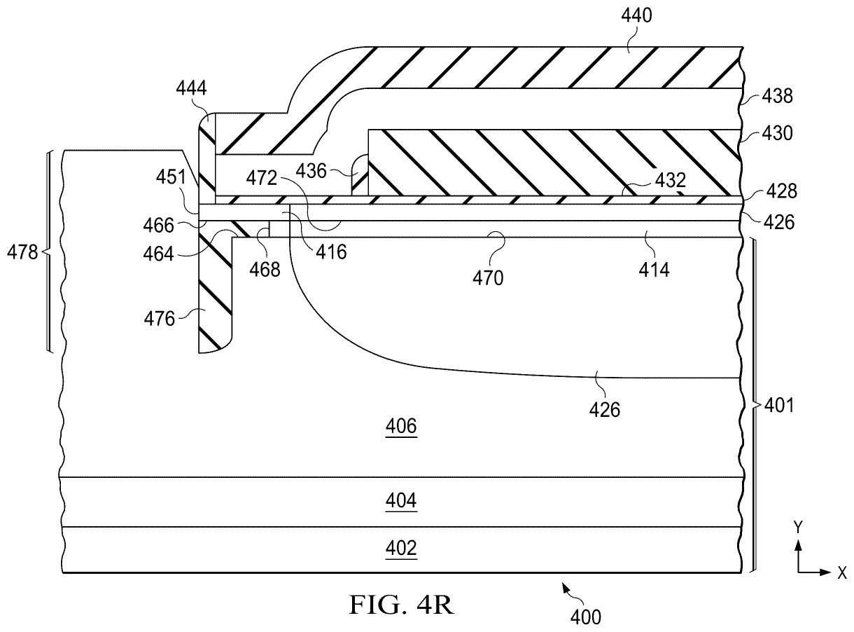

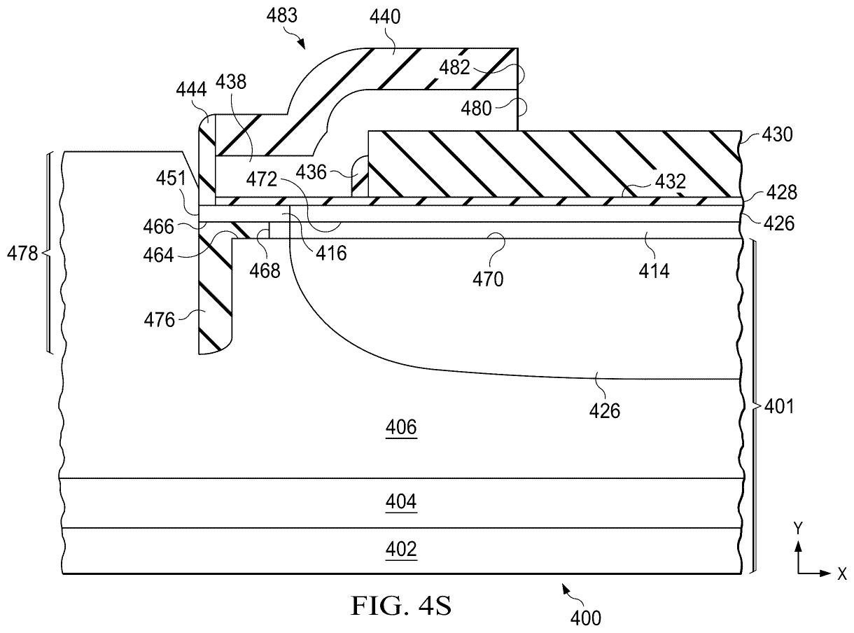

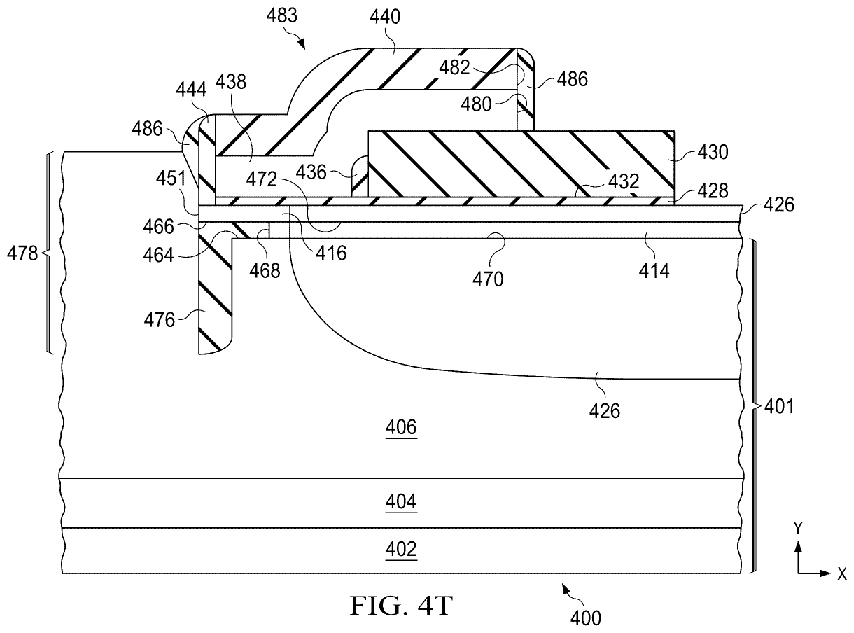

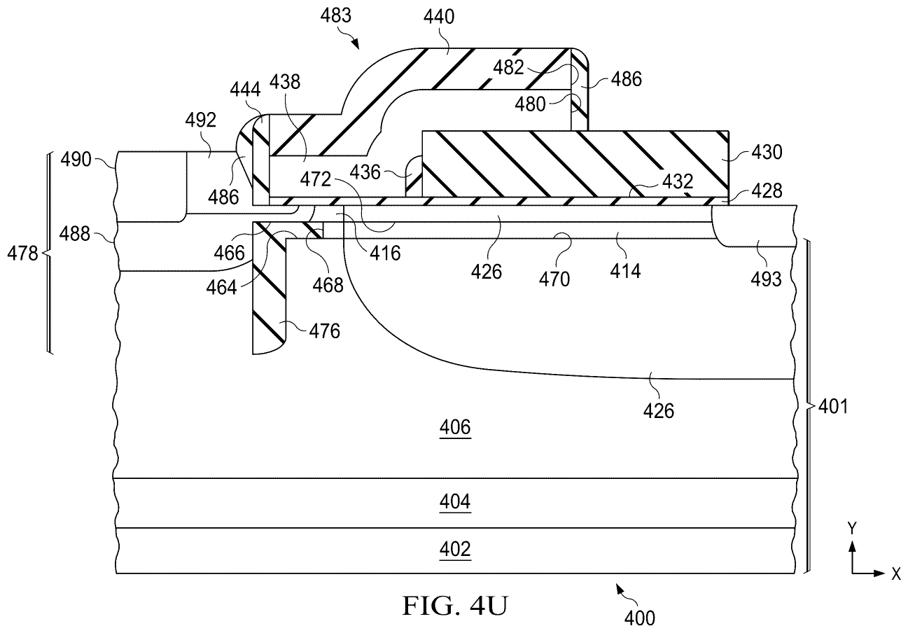

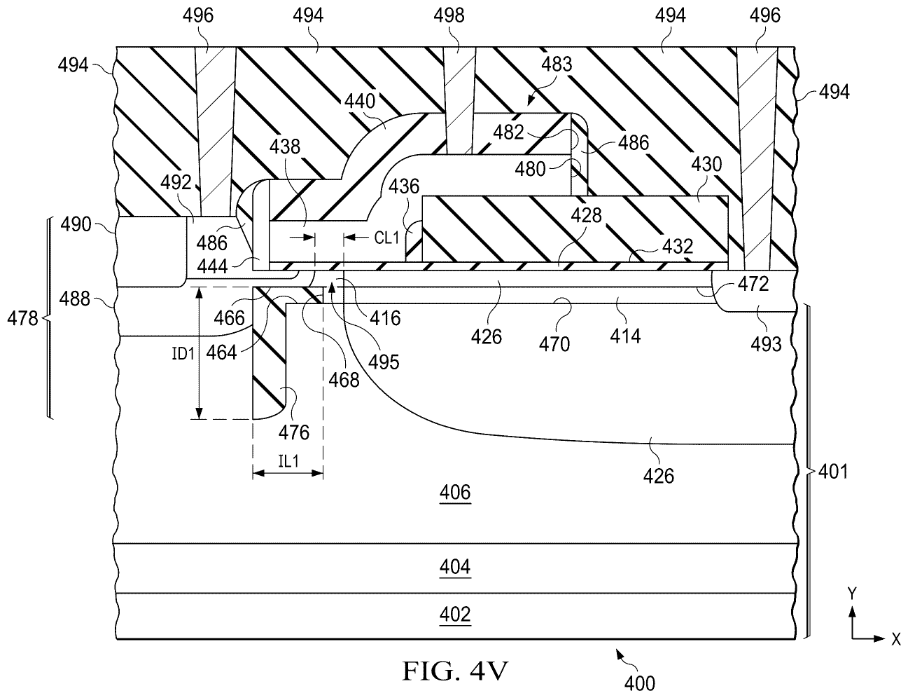

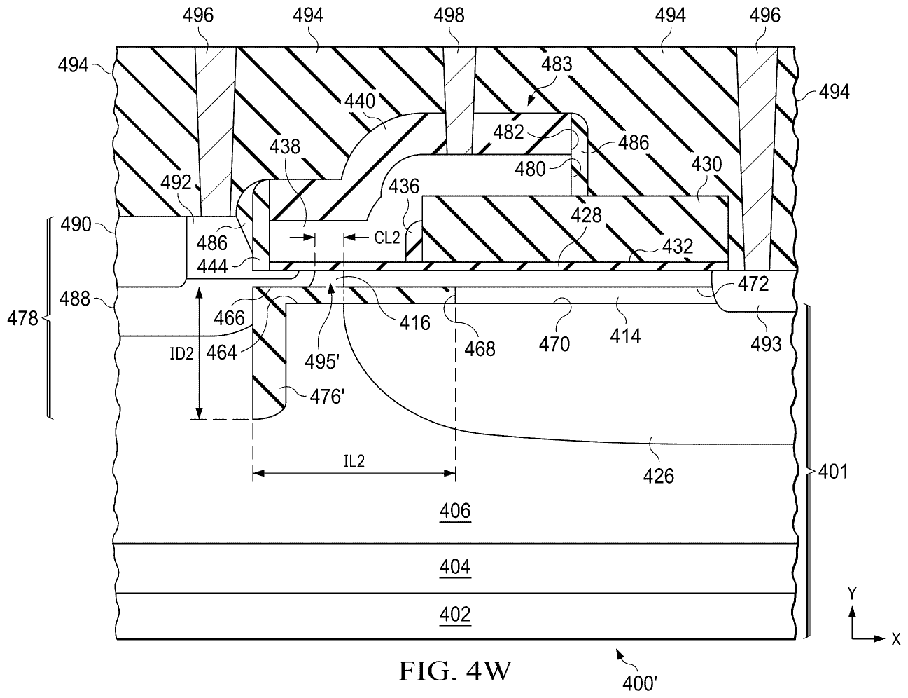

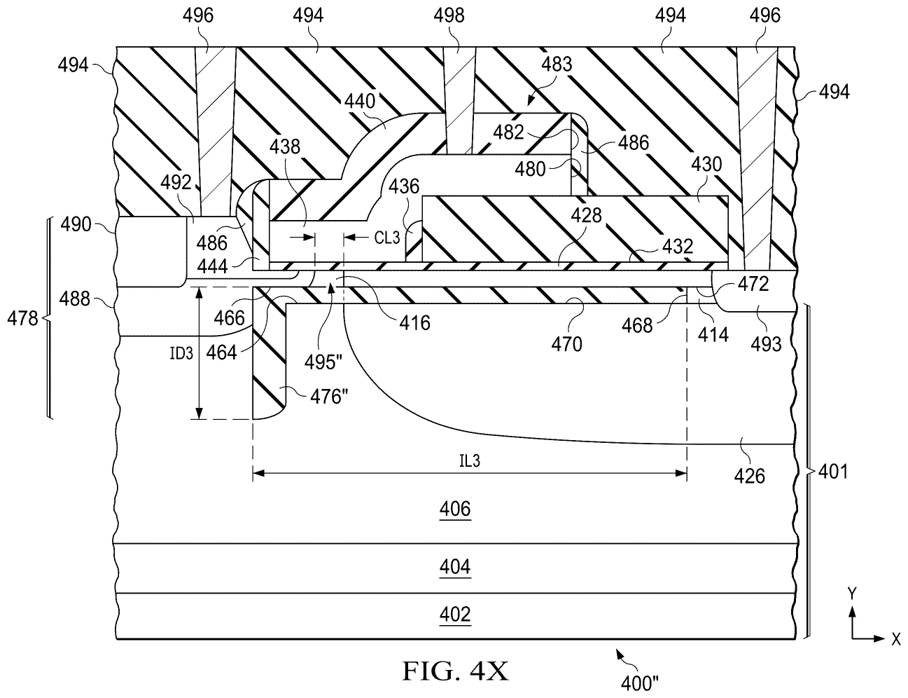

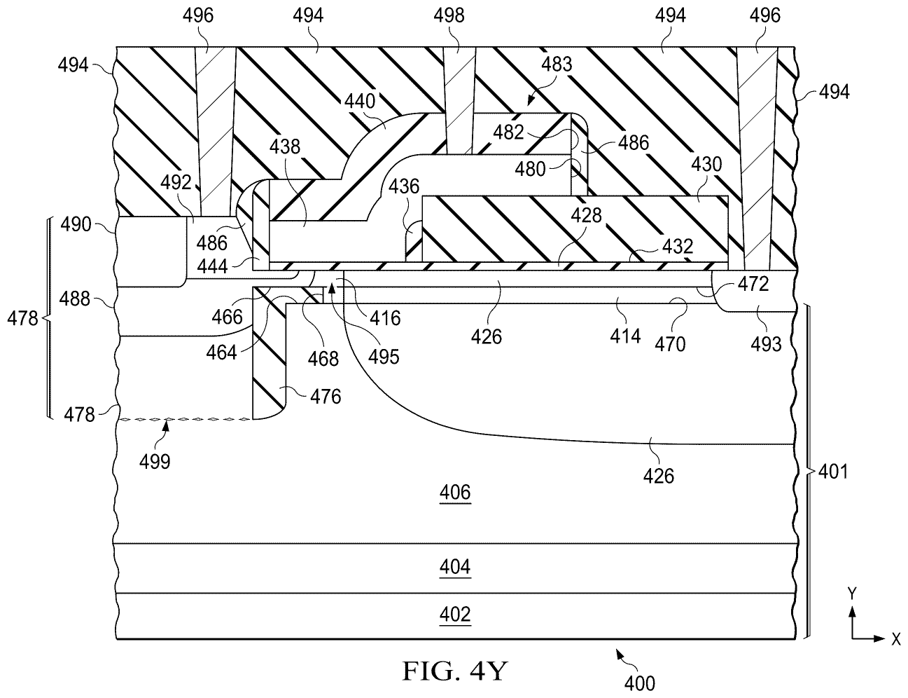

Referring now to FIG. 3, a flow diagram of a method 300 for forming an isolation structure in a field-effect-transistor (FET) to define a nanosheet channel region is illustrated, in accordance with various examples of the present disclosure. In various examples, method 300 may be used to form an isolation structure to define a nanosheet channel region in a laterally diffused metal-oxide-semiconductor (LDMOS) FET. Additional processes can be provided before, during, and after method 300. As discussed below, method 300 is described with reference to FIGS. 4A-4Y.

FIGS. 4A-4Y are diagrammatic cross-sectional views of a device 400 at various stages of fabrication (such as those associated with method 300 of FIG. 3) according to various aspects of the present disclosure. In various examples, device 400 may be a laterally diffused metal-oxide-semiconductor (LDMOS) field-effect-transistor (FET). In various examples, FIGS. 4A-4Y may illustrate cross-sectional views within region 226 of FIG. 2F and/or FIG. 2G such that device 400 builds on device 200. In various examples, device 400 may be formed before forming trenches (e.g., second trenches 224) for shallow trench isolation (STI) structures. In various examples, device 400 may be formed after completing device 200 as illustrated in FIG. 2G. Additional features can be added to device 400, and some features described below can be replaced, modified, or eliminated in other examples of device 400.

At step 302 of FIG. 3, a substrate having a first semiconductor material layer and a second semiconductor material layer is received. As shown in FIG. 4A, device 400 includes a substrate 401, a first semiconductor material layer 414, and a second semiconductor material layer 416. In various examples, substrate 401 may include a first doped semiconductor layer 402 that may be p-type, a buried layer 404 that may be n-type, and a second doped semiconductor layer 406 that may be p-type. Substrate 401, first semiconductor material layer 414, and second semiconductor material layer 416 may be formed similar to the steps described above with respect to FIGS. 2A-2F.

As will be discussed in further detail below, a portion of second semiconductor material layer 416 will become a thin channel layer, or region, of device 400. The thickness of the thin channel layer may be defined by the thickness of second semiconductor material layer 416. Additionally, as will be discussed in further detail below, a portion of first semiconductor material layer 414 will be removed to define an area to be filled by an isolation structure. As a result, the isolation structure defines, at least in part, a bottom limit of the thin channel layer thereby providing sufficient separation of the thin channel layer from substrate 401 in order to reduce short channel effects in device 400. In various examples, the thickness of second semiconductor material layer 416 may be about 5 nm to about 300 nm, and more specifically about 10 nm to about 200 nm. The thickness of second semiconductor material layer 416 may be lower (e.g., about 5 nm to about 50 nm) in devices intended to have a fully depleted channel region during operation of such devices and greater (e.g., about 100 nm to about 300 nm) in devices having a partially depleted region during operation of such devices.

At step 304 of FIG. 3, a drift region is formed in the first semiconductor material layer, the second semiconductor material layer, and the substrate. As shown in FIG. 4A, a drift region 426 extends through second semiconductor material layer 416, first semiconductor material layer 414, and into substrate 401 (e.g., second doped semiconductor layer 406). In various examples, drift region 426 may be an n-type drift region or a p-type drift region depending on the polarities, or conductivity type, of substrate 401 (e.g., first doped semiconductor layer 402, buried layer 404, and/or second doped semiconductor layer 406). In various examples, drift region 426 may be doped to a different polarity, or conductivity type, than the surrounding second doped semiconductor layer 406. For example, and for purposes of discussion below, drift region 426 may be an n-type drift region disposed in second doped semiconductor layer 406. In various examples, an average dopant density of drift region 426 may be about 1×10¹⁵ cm⁻³ to about 1×1⁰¹⁷ cm⁻³, and more specifically, about 5×10¹⁵ cm⁻³ to about 5×10¹⁶ cm⁻³. Drift region 426 may have a heavier-doped top portion (e.g., in the positive y-direction) and a lighter doped bottom portion (e.g., in the negative y-direction), to provide desired values of breakdown voltage and specific resistance for device 400.

At step 306 of FIG. 3, a gate dielectric layer is formed on the second semiconductor material layer and the drift region. As shown in FIG. 4B, a gate dielectric layer 428 is formed on device 400. In various examples, gate dielectric layer 428 is formed on second semiconductor material layer 416 and drift region 426. Gate dielectric layer 428, in various examples, may include any gate dielectric material including a high-k dielectric material. For example, gate dielectric layer 428 many include dielectric materials such as silicon dioxide, hafnium oxide, and/or zirconium oxide. In various examples, gate dielectric layer 428 may be formed by thermal oxidation, one or more chemical vapor deposition (CVD) processes, and/or exposure to a nitrogen-containing plasma.

At step 308 of FIG. 3, a field relief insulator is formed on the gate dielectric layer. As shown in FIG. 4B, field relief insulator 430 is formed on gate dielectric layer 428. In various examples, field relief insulator 430 may include an oxide, such as for example, silicon oxide. In various examples, field relief insulator 430 may include a nitride, such as for example, silicon nitride and/or silicon oxynitride. In various examples, field relief insulator 430 may include a low-k dielectric material such as a dielectric material having a dielectric constant of about 2.2 to about 2.7. Field relief insulator 430 may be formed on gate dielectric layer 428 by one or more CVD processes, physical vapor deposition (PVD) processes, and/or chemical-enhanced CVD (PECVD), among others. In various examples, field relief insulator 430 may be grown using a furnace thermal oxidation process. In various examples, growing field relief insulator 430 may include ramping a temperature of a furnace to about 900° C. to about 1100° C. The ramping of the temperature may occur over about 45 minutes to about 90 minutes. In various examples, the furnace may have an ambient oxygen percentage of about 1% to about 15%, and more specifically about 2% to about 10%. While maintaining the temperature of the furnace, the percentage of ambient oxygen may be increased to about 80% to about 95% over about 5 minutes to about 30 minutes, and more specifically, about 10 minutes to about 20 minutes. In various examples, a hydrogen chloride gas may be introduced to the furnace while maintain the ambient oxygen percentage of the furnace. In various examples, a nitrogen gas may be introduced to the furnace to purge the ambient oxygen so that the temperature of the furnace ramps down in a nitrogen rich environment.

Referring now to FIG. 4C, a portion of field relief insulator 430 is removed exposing a top surface 432 of gate dielectric layer 428. In various examples, field relief insulator 430 is removed over second semiconductor material layer 416 and a portion of drift region 426. In various examples, one or more etching processes may be performed to remove the portion of field relief insulator 430.

At step 310 of FIG. 3, a first spacer is formed on the field relief insulator. As shown in FIG. 4D, a first dielectric layer 434 is formed on device 400. In various examples, first dielectric layer 434 is formed on top surface 432 of gate dielectric layer 428 and on field relief insulator 430. In various examples, first dielectric layer 434 may include one or more layers of an oxide (e.g., silicon oxide) or a nitride (e.g., silicon nitride). First dielectric layer 434 may be formed using any known process, such as for example, chemical vapor deposition (CVD), and/or physical vapor deposition (PVD), among others.

Referring now to FIG. 4E, first dielectric layer 434 is patterned to form a first spacer 436 disposed on field relief insulator 430 and on top of gate dielectric layer 428. As shown, first spacer 436 is disposed on a sidewall of field relief insulator 430 and on top surface 432 of gate dielectric layer 428. In various examples, an etching process may be performed to remove a majority of first dielectric layer 434 such that a portion of first dielectric layer 434 remains, the remaining portion of first dielectric layer 434 being first spacer 436. In various examples, the etching process may include an anisotropic etch such as a reactive ion etch (RIE) process that removes the majority of first dielectric layer 434 leaving first spacer 436.

At step 312 of FIG. 3, a gate electrode layer is formed on the field relief insulator, the first spacer, and the gate dielectric layer. As shown in FIG. 4F, a gate electrode layer 438 is formed on device 400. Gate electrode layer 438 may be formed on top surface 432 of gate dielectric layer 428, first spacer 436, and field relief insulator 430. Gate electrode layer 438 may, in various examples, include polycrystalline silicon, also referred to as polysilicon, titanium nitride, and/or other metals and metal alloys. In various examples, gate electrode layer 438 may be doped with n-type dopants or p-type dopants, depending on the polarity of the other materials as previously discussed. In various examples, gate electrode layer 438 may be about 200 nm to about 900 nm thick, and more specifically, about 300 nm to about 800 nm thick.

Additionally, a hard mask 440 may be formed on gate electrode layer 438. In various examples, hard mask 440 may include an amorphous carbon, titanium nitride, tantalum nitride, and/or one or more metals or metal alloys.

At step 314 of FIG. 3, a second spacer is formed on a sidewall of the gate electrode layer. In various examples, as discussed below, the gate electrode layer and the hard mask are patterned and then a second spacer is formed on the sidewall of the patterned gate electrode layer and a sidewall of the patterned hard mask. Referring now to FIG. 4G, a portion of gate electrode layer 438 and a portion of hard mask 440 over second semiconductor material layer 416 are removed. Removing the portion of gate electrode layer 438 and hard mask 440 exposes top surface 432 of gate dielectric layer 428 and sidewalls of gate electrode layer 438 and hard mask 440. One or more etching processes may be performed to remove the portions of gate electrode layer 438 and hard mask 440. In various examples, a first etching process may be performed to remove the portion of hard mask 440 and then a second etching process may be performed to remove the portion of gate electrode layer 438. In various examples, an etch mask such as a photoresist layer may be used for each etching process. In various examples, the etching process may be a reactive ion etch (RIE) process. In various examples, the RIE process may use fluorine radicals.

Next, referring now to FIG. 4H, a second dielectric layer 442 is formed on device 400. In various examples, second dielectric layer 442 may be an oxide layer or a nitride layer. Second dielectric layer 442 may be formed on top surface 432 of gate dielectric layer 428, gate electrode layer 438, and hard mask 440 including the sidewalls of gate electrode layer 438 and hard mask 440. In various examples, second dielectric layer 442 may include silicon nitride, silicon oxynitride, or another nitride composition.

Referring now to FIG. 4I, a second spacer 444 is formed and used as a mask to form a trench 446. A majority of second dielectric layer 442 may be removed to form second spacer 444 on the sidewalls of gate electrode layer 438 and hard mask 440 and on top surface 432 of gate dielectric layer 428. In various examples, one or more etching processes may be performed to remove the majority of second dielectric layer 442. In various examples, the one or more etching processes may include a dry etching process. In various examples, the one or more etching processes may use tetrafluoromethane (CF₄), nitrogen (N₂), oxygen (O₂), and/or difluoromethane (CH₂F₂), among other etchants.

Trench 446 may then be formed in a first direction (e.g., in the negative y-direction) using second spacer 444 as an etch mask. Trench 446 may expose a top surface 448 of substrate 401, and more specifically, second doped semiconductor layer 406. Also, first sidewall surface 449 of first semiconductor material layer 414 and second sidewall surface 451 of second semiconductor material layer 416 are exposed in trench 446. In various examples, one or more etching processes may be performed to remove portions of gate dielectric layer 428, second semiconductor material layer 416, and first semiconductor material layer 414 not covered by second spacer 444 and/or hard mask 440. For example, a first etching process may be used to remove portions of gate dielectric layer 428 thereby exposing second semiconductor material layer 416, a second etching process may be used to remove portions of second semiconductor material layer 416 thereby exposing first semiconductor material layer 414, and a third etching process may be used to remove portions of first semiconductor material layer 414 to expose top surface 448, first sidewall surface 449, and second sidewall surface 451. In various example, one etching process may be used to remove portions of gate dielectric layer 428, to remove portions of second semiconductor material layer 416, and to remove portions of first semiconductor material layer 414 to expose top surface 448 of substrate 401. In various examples, the one or more etching processes may include a wet etch, a dry etch, and/or a combination thereof.

At step 316 of FIG. 3, a third spacer is formed on the second spacer. As shown in FIG. 4J, a third dielectric layer 450 is formed on device 400. In various examples, third dielectric layer 450 may be an oxide layer or a nitride layer. In various examples, third dielectric layer 450 may include silicon-oxide, silicon-dioxide, silicon-nitride, and/or silicon-oxynitride. Third dielectric layer 450 may be formed on hard mask 440, second spacer 444, and in trench 446 including on top surface 448, first sidewall surface 449 of first semiconductor material layer 414, and second sidewall surface 451 of second semiconductor material layer 416. In various examples, third dielectric layer 450 may be formed using a chemical vapor deposition (CVD) process, a physical vapor deposition (PVD) process, and/or a thermal furnace process, among others.

Referring now to FIG. 4K, third dielectric layer 450 is patterned to form a third spacer 452 on device 400 and remove a portion of substrate 401 through trench 446 to thereby form an extended trench 447. A majority of third dielectric layer 450 may be removed to form third spacer 452 on first sidewall surface 449, second sidewall surface 451, and second spacer 444. In various examples, the portions of third dielectric layer 450 that are removed may be removed using one or more etching processes. In various examples, the one or more etching processes may include a wet etch process, a dry etch process, and/or a combination thereof. In various examples, the one or more etching processes may include the use of hydrofluoric acid (HF) and/or other chemical etchants.

As shown in FIG. 4K, trench 446 may be extended in the first direction (e.g., in the negative y-direction) by removing material from second doped semiconductor layer 406 to thereby form extended trench 447. Top surface 456 and a sidewall 458 of second doped semiconductor layer 406 are exposed within extended trench 447. In various examples, one or more etching processes may be performed to remove material from second doped semiconductor layer 406 with little to no material removed from third spacer 452 and/or hard mask 440. In various examples, the one or more etching processes may be an anisotropic etching process that is configured to remove material from substrate 401 in the first direction at a higher rate than in a second direction (e.g., the positive x-direction) that is perpendicular to the first direction.

At step 318 of FIG. 3, the substrate is etched to widen the extended trench and expose a portion of the first semiconductor material layer. As shown in FIG. 4L, an undercut of second doped semiconductor layer 406 is formed, enlarging extended trench 447 laterally in the second direction (e.g., the positive x-direction) thereby forming trench 460. Trench 460 may be extended in the second direction (e.g., the positive x-direction) using one or more etching processes. Additionally, trench 460 may be extended in the first direction (e.g., in the negative y-direction), producing a top surface 457 of second doped semiconductor layer 406. The formation of trench 460 exposes a bottom surface 459 of first semiconductor material layer 414. Bottom surface 459 faces top surface 457 or away from the gate electrode layer 438.

In various examples, the one or more etching processes used to form trench 460 may have a higher selectivity for the material of second doped semiconductor layer 406 than for the material of first semiconductor material layer 414. In various examples, an etching process, such as an anisotropic etching process, that removes more material from second doped semiconductor layer 406 in the second direction than in the first direction may be used.

For example, in at least one example in which second doped semiconductor layer 406 includes silicon and first semiconductor material layer 414 includes silicon germanium, the etching process may have a Si: SiGe etch ratio of about 200:1 such that little to no material is removed from first semiconductor material layer 414 during the etching of second doped semiconductor layer 406. In various examples, the one or more etching processes may include the use of tetrafluoromethane (CF₄), nitrogen (N₂), oxygen (O₂), and/or difluoromethane (CH₂F₂), among other etchants. In various examples, the one or more etching processes may occur at a pressure of about 150 mTorr to about 1,500 mTorr, and more specifically, about 350 mTorr to about 1,200 mTorr.

At step 320, the exposed portion of the first semiconductor layer is etched to extend the trench laterally and/or deeper into second doped semiconductor layer 406. As shown in FIG. 4M, a trench 462 is formed in device 400. Trench 462 enlarges trench 460 laterally by removing a portion of first semiconductor material layer 414 that was exposed by trench 460. As discussed above, removing the portion of first semiconductor material layer 414 under second semiconductor material layer 416 defines an area to be filled by an isolation structure. The isolation structure, as will be discussed further below, defines a bottom extent of the thin channel layer of the device 400. In this example, the removal of the portion of first semiconductor material layer 414 occurs with little to no etching of second semiconductor material layer 416. However, as discussed later in other examples in reference to FIGS. 4N and 4O, the one or more etching processes may be tuned to etch the exposed first semiconductor material layer 414 and/or second doped semiconductor layer 406 thereby extending trench 462 laterally in the second direction (e.g., the positive x-direction) and/or deeper into the substrate in the first direction (e.g., in the negative y-direction).

In various examples, trench 462 exposes a top surface 464 of second doped semiconductor layer 406, a bottom surface 466 of second semiconductor material layer 416, and a sidewall surface 468 of first semiconductor material layer 414 that remains after the etching to form trench 462. As shown in FIG. 4M, trench 462 may extend laterally (e.g., in the positive x-direction) without exposing drift region 426. That is, a sufficient portion of first semiconductor material layer 414 remains after the etching to form trench 462 to prevent drift region 426 from being exposed by trench 462. In another example, the etching process used to form trench 462 may remove enough of first semiconductor material layer 414 to expose a portion of drift region 426 with little to no etching of drift region 426.

In various examples, trench 462 may be formed using one or more etching processes that are highly selective of the material of first semiconductor material layer 414 over the material of second semiconductor material layer 416 and/or second doped semiconductor layer 406. In the present example where first semiconductor material layer 414 is a SiGe layer and second semiconductor material layer 416 is a Si layer, the one or more etching processes may have a SiGe:Si etching ratio of about 150:1. In various examples, the etching process may be a dry etch process (e.g., vapor etch), a wet etch process, or a combination thereof. In various examples, the dry etch process may be a vapor etch with a high partial pressure hydrochloric acid (HCl) at pressure of about 100 Torr to about 400 Torr, and more specifically, about 200 Torr to about 300 Torr. In various examples, the dry etch process may use a combination of carbon tetrafluoride (CF₄), oxygen (O₂), and helium (He) at a low pressure of about 5 mTorr to about 150 mTorr, and more specifically, about 25 mTorr to about 125 mTorr. In various examples the wet etch process may use a mixed solution containing water (H₂O), nitric acid (HNO₃), acetic acid (CH₃COOH) and/or hydrofluoric acid (HF).

Referring now to FIG. 4N, as an alternative to trench 462 illustrated in FIG. 4M, a trench 462′ may be formed in device 400. Trench 462′ may be formed in a similar manner as discussed above with respect to trench 462 in FIG. 4M except that the etching process, such as etching time, may be altered to remove more of first semiconductor material layer 414. That is, trench 462′ may extend laterally (e.g., in the positive x-direction) through substrate 401 and into drift region 426 unlike trench 462. As shown, trench 462′ extends further laterally than trench 462 to expose a top surface 470 and a bottom surface 472 of drift region 426 after removing the portion of first semiconductor material layer 414. Accordingly, trench 462′ extends further in the second direction than trench 462. As shown, trench 462′ extends under at least a portion of the field relief insulator 430.

Referring now to FIG. 4O, as an alternative to either trench 462 and trench 462′ illustrated in FIGS. 4M and 4N, respectively, a trench 462″ may be formed in device 400. Trench 462″ may be formed in a similar manner as discussed above with respect to trench 462 and trench 462′ except that the etching process, such as etching time, may be altered to remove more of first semiconductor material layer 414. As shown, trench 462″ may extend laterally (e.g., in the positive x-direction) through substrate 401 and into drift region 426 more than either of trenches 462 or 462′. As such, trench 462″ may expose more of top surface 470 and bottom surface 472 of drift region 426 after removing the portion of first semiconductor material layer 414. Additionally, trench 462″ extends further in the second direction under the field relief insulator than trench 462′.

At step 322 of FIG. 3, a dielectric isolation structure is formed in the extended trench. As shown in FIG. 4P, a dielectric material layer 474, such as an oxide layer, is formed on device 400 within trench 462 of FIG. 4M. Specifically, dielectric material layer 474 may be formed in trench 462 and over hard mask 440. As shown, dielectric material layer 474 interfaces with at least hard mask 440, second spacer 444, third spacer 452, second semiconductor material layer 416, first semiconductor material layer 414, and substrate 401. More specifically, dielectric material layer 474 interfaces with bottom surface 466 of second semiconductor material layer 416 and sidewall surface 468 of first semiconductor material layer 414. In another one or more examples, as discussed below with reference to FIGS. 4W and 4X dielectric material layer 474 may further be formed to interface with top surface 470 and bottom surface 472 of drift region 426 when more of first semiconductor material layer 414 is removed to form trenches 462′ or 462″ as discussed in reference to FIGS. 4N and 4O. In various examples, dielectric material layer 474 may have a material composition the same or substantially similar to that of third dielectric layer 450 used to form third spacer 452. In various examples, dielectric material layer 474 may include silicon-oxide, silicon-dioxide, silicon-nitride, and/or silicon-oxynitride. Accordingly, dielectric material layer 474 may be formed in a similar manner as described above with respect to third dielectric layer 450. In various examples, dielectric material layer 474 may be formed using an atomic layer deposition (ALD) process to fill in trench 462 with dielectric materials such as silicon dioxide and/or a high-k dielectric material, among others. In some examples, the high-k dielectric material may be hafnium oxide (HfO₂), zirconium dioxide (ZrO₂), and/or aluminum oxide (Al₂O₃), among others. In various examples, the ALD process may be used to fill narrower (e.g. smaller) regions of trench 462 such as the portion of trench 462 that was previously occupied by the portions of first semiconductor material layer 414. In some examples, the ALD process may be used to fill the entire trench 462 with dielectric material or in other examples a remaining portion of trench 462 may be unfilled by the ALD process. In various examples, the ALD process may be followed by a flowable chemical vapor deposition (FCVD) process to fill a remainder portion of trench 462 with an oxide material that was not filled via the ALD process. For example, the portion of extended trench 462 that extends laterally toward drift region 426 (previously occupied by first semiconductor material layer 414) is filled in whole and/or part via a first deposition process, such as an ALD process, and the remaining portion of trench 462 is filled via a second deposition process, such as an FCVD process. As such, in some examples, dielectric material 474 layer may be formed of more than one dielectric material layers have the same or different material compositions. It is also understood, in various examples, the entirety of trench 462 may be filled via a single deposition process.

Referring now to FIG. 4Q, dielectric material layer 474 is selectively etched, using second spacer 444 and hard mask 440, to form a dielectric isolation structure 476. As previously discussed, dielectric isolation structure 476 is formed such that it defines a bottom extent of the thin channel layer (e.g. nanosheet channel layer). That is, dielectric isolation structure 476 separates second semiconductor material layer 416 from second doped semiconductor layer 406 to define the thin channel layer for device 400. Reducing the thickness of the thin channel layer using dielectric isolation structure 476 is expected to reduce the short channel effects caused by a shortened channel region. That is, the reduced thickness of second semiconductor material layer 416 as defined by dielectric isolation structure 476 tends to enable a lesser doping concentration in the thin channel layer (e.g., second semiconductor material layer 416), while reducing short channel effects and improving performance of device 400. As shown, portions of dielectric material layer 474 are removed to form dielectric isolation structure 476. The removal of theses portions of dielectric material layer 474 may occur via an etching process selective to the composition of dielectric material layer 474. It is noted that, as illustrated, when third spacer 452 has a same or similar composition as dielectric material layer 474, third spacer 452 may, in various examples, be consumed and removed during the formation of dielectric isolation structure 476. Additionally, a trench 477 is formed as a result of the removal of the portions of dielectric material layer 474 and/or third spacer 452 adjacent the dielectric isolation structure 476.

Dielectric isolation structure 476 may, in various examples interface (e.g. physically contact or touch) bottom surface 466 of second semiconductor material layer 416, sidewall surface 468 of first semiconductor material layer 414, and substrate 401. In another one or more examples, as discussed below with reference to FIGS. 4W and 4X dielectric isolation structure 476 may further be formed to interface with top surface 470 and bottom surface 472 of drift region 426 when more of the first semiconductor material layer 414 is removed to form trenches 462′ or 462″ as discussed in reference to FIGS. 4N and 40. Accordingly, dielectric isolation structure 476 may extend laterally (e.g., in the positive x-direction) as desired depending on how much of first semiconductor material layer 414 is removed in forming a trench beforehand (e.g. trenches 462, 462′ or 462″).

At step 324 of FIG. 3, a third semiconductor material layer is formed adjacent the dielectric isolation structure. As shown in FIG. 4R, a third semiconductor material layer 478 is formed on device 400 and in trench 477. In various examples, third semiconductor material layer 478 may be a semiconductor material that includes substantially pure Si and/or SiGe. Third semiconductor material layer 478 may be the same material as second doped semiconductor layer 406. In various examples, third semiconductor material layer 478 may be epitaxially grown from top surface 457 of second doped semiconductor layer 406. In various examples, third semiconductor material layer 478 may be grown from second doped semiconductor layer 406 and/or second semiconductor material layer 416 in trench 477, to about a height (e.g., in the positive y-direction) of gate dielectric layer 428 or may be grown to a height above gate dielectric layer 428. In various examples, epitaxial growth of third semiconductor material layer 478 may be achieved by a molecular beam epitaxy (MBE) process, a chemical vapor deposition (CVD) process, a metalorganic chemical vapor deposition (MOCVD) process, other suitable epitaxial growth process, or combinations thereof.

At step 326 of FIG. 3, the gate electrode layer is patterned to form a gate structure and a spacer feature is formed on the gate structure. As shown in FIG. 4S, a portion of hard mask 440 and a portion of gate electrode layer 438 are removed via a patterning process to form gate structure 483. As one skilled in the art would understand, gate structure 483 includes one or more layers such as hard mask 440, gate electrode layer 438, and gate dielectric layer 428. Removing the portions of hard mask 440 and gate electrode layer 438 exposes a sidewall 480 of gate electrode layer 438 and a sidewall 482 of hard mask 440. In various examples, the remaining portion of hard mask 440 and gate electrode layer 438 are disposed over field relief insulator 430, first spacer 436, and gate dielectric layer 428.

In various examples, one or more etching processes may be performed to remove the portions of hard mask 440 and gate electrode layer 438. For example, a first etching process may be performed to remove the portion of hard mask 440 and a second etching process may be performed to remove the portion of gate electrode layer 438. An etch mask (e.g., photoresist) may be used for each of the one or more etching processes.

Referring now to FIG. 4T, a gate spacer 486 is formed on gate structure 483 of device 400. Gate spacer 486 may, in various examples, be formed in a similar manner as second spacer 444 described above. In various examples, a dielectric material may be formed on device 400 and the dielectric material may be etched to form gate spacer 486 on sidewall 480 of gate electrode layer 438 and sidewalls of hard mask 440, including sidewall 482, and on a top surface of field relief insulator 430.

Also, shown in FIG. 4T a portion of field relief insulator 430 and gate dielectric layer 428 are removed, exposing a top surface of drift region 426. The portions of field relief insulator 430 and gate dielectric layer 428 may be removed, in various examples, using one or more etching processes. For example, a first etching process may remove the portion of field relief insulator 430 and a second etching process may remove the portion of gate dielectric layer 428. Etching processes for removing field relief insulator 430 and gate dielectric layer 428 have been previously described herein in at least FIGS. 4C and 4I.

At step 328 of FIG. 3, a body diffusion region, a body region, a source region, and a drain region are formed. As shown in FIG. 4U, a body diffusion region 488, a body region 490, a source region 492, and a drain region 493 are formed on device 400. Body diffusion region 488, body region 490, and source region 492 may be formed in the third semiconductor material layer 478 and drain region 493 may be formed in drift region 426. In various examples, each of body diffusion region 488, body region 490, source region 492, and drain region 493 may doped to be an n-type region or a p-type region. As illustrated and described herein, when device 400 is an n-type LDMOS FET, body diffusion region 488 may be an n-type region, body region 490 may be a p-type region, source region 492 may be an n-type region, and drain region 493 may be an n-type region. In various examples, the body diffusion region 488 may be doped by an angled implant and the dopants may diffuse into second semiconductor material layer 416 adjacent dielectric isolation structure 476. In various examples, dielectric isolation structure 476 may abut body diffusion region 488 and/or may extend into body diffusion region 488. That is, body diffusion region 488 is doped around dielectric isolation structure 476. Drain region 493 may be formed in first semiconductor material layer 414 and second semiconductor material layer 416 in addition to drift region 426.

At step 330 of FIG. 3, contacts are formed. As shown in FIG. 4V, an interlayer dielectric layer 494, source/drain contacts 496, and a gate contact 498 are formed on device 400. Interlayer dielectric layer 494 may be formed over device 400 including over hard mask 440, second spacer 444, gate spacer 486, body region 490, source region 492, and drain region 493. In various examples, interlayer dielectric layer 494 may include an oxide and/or a nitride material. In various examples, interlayer dielectric layer 494 may be planarized using a chemical mechanical polishing (CMP) process or other similar process. Openings may then be formed through interlayer dielectric layer 494, a first opening through hard mask 440 and exposing gate electrode layer 438, a second opening exposing source region 492, and a third opening exposing drain region 493. Gate contact 498 may be formed in the first opening and on gate electrode layer 438 and source/drain contacts 496 may be formed in the second and third openings and on source region 492 and drain region 493. In various examples, gate contact 498 and source/drain contacts 496 may include a metal and/or a metal alloy as well as a liner material layer at least partially surrounding the metal and/or metal alloy.

As discussed above, current laterally diffused metal-oxide-semiconductor (LDMOS) field-effect transistors (FETs) may experience short channel effects as they are scaled down. As the channel region of the LDMOS is scaled down the current leakage through the channel during use tends to increase. Typically, a higher dopant concentration in the channel region is used to address this issue. However, a higher dopant concentration in the channel region tends to result in reduced channel mobility.

To address these issues, in reference to FIG. 4V, device 400 includes a thin channel region 495 (e.g. a nanosheet channel region) defined in part by dielectric isolation structure 476. As shown, dielectric isolation structure 476 has a lateral isolation length IL1 extending in the direction of the transistor's channel length CL1 and a vertical isolation depth ID1 extending deeper into the substrate (e.g., along the y-axis). Specifically, lateral isolation length IL1 of dielectric isolation structure 476 extends from body diffusion region 488 through substrate 401 and toward drift region 426. As a result, thin channel region 495 (e.g., second semiconductor material layer 416) is bounded on a bottom side (e.g., in the negative y-direction) by dielectric isolation structure 476. While dielectric isolation structure 476 does not fully extend to drift region 426 under thin channel region 495, there is sufficient separation of thin channel region 495 from substrate 401 to reduce the short channel effects of device 400.

Accordingly, the thin channel region 495 defined by the dielectric isolation structure 476 tends to improve gate control of the semiconductor device by reducing the short channel effect. Specifically, the thin silicon channel region that is partially defined by the dielectric isolation structure has a reduced doping concentration than would otherwise be used in such scaled down devices as an LDMOS FET. This relatively reduced doping concentration provides the benefits of increased channel mobility and/or reduce channel resistivity. In various examples, thin channel region 495 may have a channel dopant concentration as low as about 5×10¹⁶ cm⁻³ to about 1×10¹⁹ cm^{-3,} and more specifically, about 1×10¹⁷ cm⁻³ to about 4×10¹⁸ cm⁻³. In various examples, the doping concentration may be design dependent such as based on a thickness of thin channel region 495.

Additionally, as shown in FIG. 4V, dielectric isolation structure 476 has a vertical isolation depth ID1 extending deeper into the substrate (e.g., along the y-axis). In various examples, the vertical isolation depth ID1 of dielectric isolation structure 476 may vary depending on the application usage of the transistor (e.g. voltage applied to drain side of the semiconductor device). In various examples, the depth of the isolation structure may be made deeper when the transistor is a higher voltage transistor (e.g. applied voltage to the drain is higher) and may be made shallower when the transistor is a lower voltage transistor (e.g. the supplied voltage to the drain is lower).

In various examples, the lateral length of the dielectric isolation structure may be modified to alter the gate control of the device with little to no change in the drain-source resistance. Referring now to FIGS. 4W and 4X, alternatives to device 400 illustrated in FIG. 4V are shown in which the lateral length of the dielectric isolation structure differs from device 400. Device 400′ illustrated in FIG. 4W and device 400″ in FIG. 4X are substantially similar to device 400 except for the formation of the respective dielectric isolation structures. As discussed above, FIGS. 4W and 4X illustrate the subsequent formation of the dielectric isolation structure within trench 462′ and 462″, respectively, as described above with respect to FIGS. 4N and 4O. Specifically, more of first semiconductor material layer 414 is progressively removed during the respective formation of trenches 462′ and 462″ such that the trenches extend laterally to within drift region 426. As such, the formation of dielectric isolation structure 476′ or 476″ within trench 462′ or 462″, respectively, results in the dielectric isolation structures interfacing with top surface 470 and bottom surface 472 of drift region 426. Accordingly, dielectric isolation structure 476′ of device 400′ extends further in the second direction than dielectric isolation structure 476 of device 400 and dielectric isolation structure 476″ of device 400″ extends further in the second direction than dielectric isolation structure 476′ of device 400′. As shown in FIG. 4W and 4X, dielectric isolation structures 476′ and 476″ extend to different lengths under the field relief insulator 430. All other processing steps are the same as described above.

In device 400′ of FIG. 4W, dielectric isolation structure 476′ has a lateral isolation length IL2 extending in the direction of the transistor's channel length CL2 and a vertical isolation depth ID2 extending deeper into the substrate (e.g., along the y-axis). Specifically, lateral isolation length IL2 of dielectric isolation structure 476′ extends from body diffusion region 488 through substrate 401 and into drift region 426. As a result, thin channel region 495′ (e.g., second semiconductor material layer 416) is bounded on a bottom side (e.g., in the negative y-direction) by dielectric isolation structure 476′ further in the lateral direction than compared to device 400. That is, the lateral isolation length IL2 of dielectric isolation structure 476′ provides more isolation for thin channel region 495′ than the lateral isolation length IL1 of dielectric isolation structure 476 in device 400. This additional isolation tends to further reduce the short channel effects and improve the gate control of device 400′.

In device 400″ of FIG. 4X, dielectric isolation structure 476″ has a lateral isolation length IL3 extending in the direction of the transistor's channel length CL3 and a vertical isolation depth ID3 extending deeper into the substrate (e.g., along the y-axis). Specifically, lateral isolation length IL3 of dielectric isolation structure 476″ extends from body diffusion region 488 through substrate 401 and into drift region 426. Specifically, dielectric isolation structure 476″ in device 400″ extends further into drift region 426 than dielectric isolation structure 476′ of device 400′. As a result, thin channel region 495″ (e.g., second semiconductor material layer 416) is bounded on a bottom side (e.g., in the negative y-direction) by dielectric isolation structure 476″ further in the lateral direction than compared to devices 400 and 400′. Accordingly, dielectric isolation structure 476″ having lateral isolation length IL3 tends to provide additional isolation of the channel layer over dielectric isolation structures 476 and 476′ of devices 400 and 400′, respectively. This additional isolation tends to further reduce the short channel effects and improve the gate control of device 400″.

Referring now to FIG. 4Y, voids 499 are illustrated in device 400. Specifically, voids 499, or dislocations may occur during the formation of third semiconductor material layer 478 discussed above with respect to step 324 of FIG. 3. In various examples, voids 499 may occur along the transition line between substrate 401, or more specifically second doped semiconductor layer 406, and the newly formed third semiconductor material layer 478. All other features shown in FIG. 4Y are described with respect to device 400 shown in FIG. 4V.

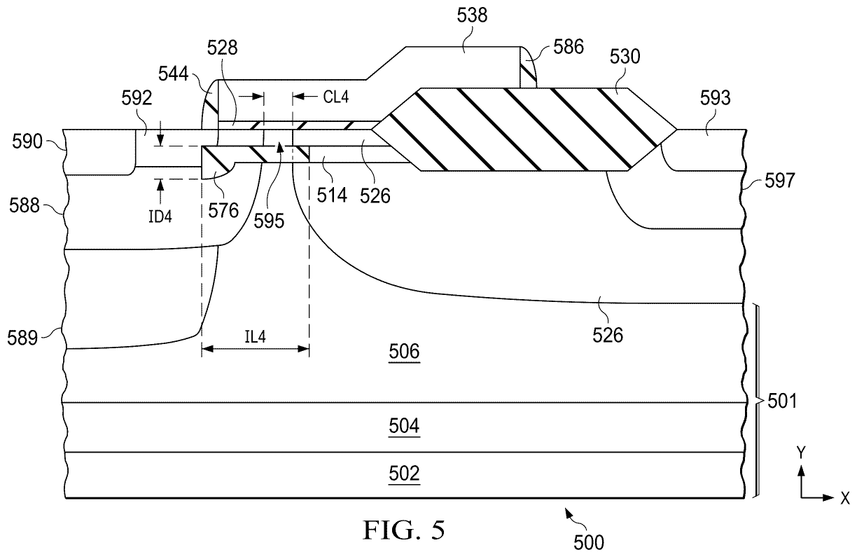

Referring now to FIG. 5, a diagrammatic cross-sectional view of a device 500 is illustrated, according to various aspects of the present disclosure. Device 500 may be fabricated using method 100 and/or method 300 as illustrated in FIG. 1 and FIG. 3, respectively. In various examples, device 500 may be a laterally diffused metal-oxide-semiconductor (LDMOS) field-effect-transistor (FET). As such, device 500 includes similar components as device 400, including a substrate 501, a first p-type semiconductor layer 502, a n-type buried layer 504, a second p-type semiconductor layer 506, a first semiconductor material layer 514, a thin channel region 595 (e.g., a second semiconductor material layer), a drift region 526, a gate dielectric 528, a gate electrode 538, a nitride spacer 544, an dielectric isolation structure 576, a gate spacer 586, a body diffusion region 588, a body region 590, a source region 592, a drain region 593, channel length CL4, source/drain contacts, and a gate contact, descriptions of which will not be repeated below.

Device 500 further includes a local oxidation of silicon (LOCOS) oxide 530, a first deep well 589, and a second deep well 597. In various examples, first deep well 589 and second deep well 597 may be doped to as n-type or p-type depending on the polarities of the device and surrounding regions. As has been described herein and for discussion purposes, first deep well 589 may be doped to be p-type and second deep well 597 may be doped to be n-type. First deep well 589 is disposed in substrate 501 and beneath (e.g., in the negative y-direction) body diffusion region 588. Second deep well 597 is disposed in drift region 526 and beneath LOCOS oxide 530 and second source/drain region 593.

LOCOS oxide 530 may be formed having a first bird's beak edge shape at a first end (e.g., in the negative x-direction) that is disposed over drift region 426 and second bird's beak edge shape at a second end (e.g., in the positive x-direction) that is disposed over second source/drain region 593. That is, LOCOS oxide 530 has a have a tapered profile at its lateral edges (e.g., in the x-directions), that is commonly referred to as a bird's beak. In various examples, LOCOS oxide 530 may be formed by forming a mask layer (e.g., silicon nitride) over a layer of LOCOS pad oxide (e.g., gate dielectric layer 428) over substrate 501. Portions of the mask layer are removed exposing the LOCOS pad oxide. A thermal oxidation process forms silicon dioxide in the areas exposed by the mask layer by thermal oxidation, to form LOCOS oxide 530.

As illustrated in FIG. 5, device 500 has a thin channel region 595 (e.g. a nanosheet channel region) defined in part by dielectric isolation structure 576. As shown, dielectric isolation structure 576 has a lateral isolation length IL4 extending in the direction of the transistor's channel length CL4 and a vertical isolation depth ID4 extending deeper into the substrate (e.g., along the y-axis). Specifically, lateral isolation length IL4 of dielectric isolation structure 576 extends from source region 592, through at least portions of body diffusion region 588, second p-type semiconductor layer 506, and into drift region 526 where dielectric isolation structure 576 interfaces with first semiconductor material layer 514. Thus, dielectric isolation structure 576 spans a longer distance than channel length CL4. This additional isolation tends to further reduce the short channel effects and improve the gate control of device 500. In various examples, dielectric isolation structure 576 may extend further into drift region 526 (e.g., in the positive x-direction) and/or deeper (e.g., in the negative y-direction) into body diffusion region 588.

Dielectric isolation structure 576 has a vertical isolation depth ID4 extending deeper into the substrate (e.g., along the y-axis). In various examples, vertical isolation depth ID4 may be less than, greater than, or equal to any of the various vertical isolation depths (e.g. ID1-ID3) discussed with respect to devices 400, 400′ and 400″. In various examples, the vertical depth of the dielectric isolation structure 576 may vary depending on the application usage of the transistor (e.g., voltage applied to drain side of the semiconductor device). In various examples, the depth of dielectric isolation structure 576 may be made deeper when the transistor is a higher voltage transistor (e.g. applied voltage to the drain is higher) and may be made shallower when the transistor is a lower voltage transistor (e.g. the supplied voltage to the drain is lower). Accordingly, vertical isolation depth ID4 of dielectric isolation structure 576 may be modified to improve the gate control of device 500.

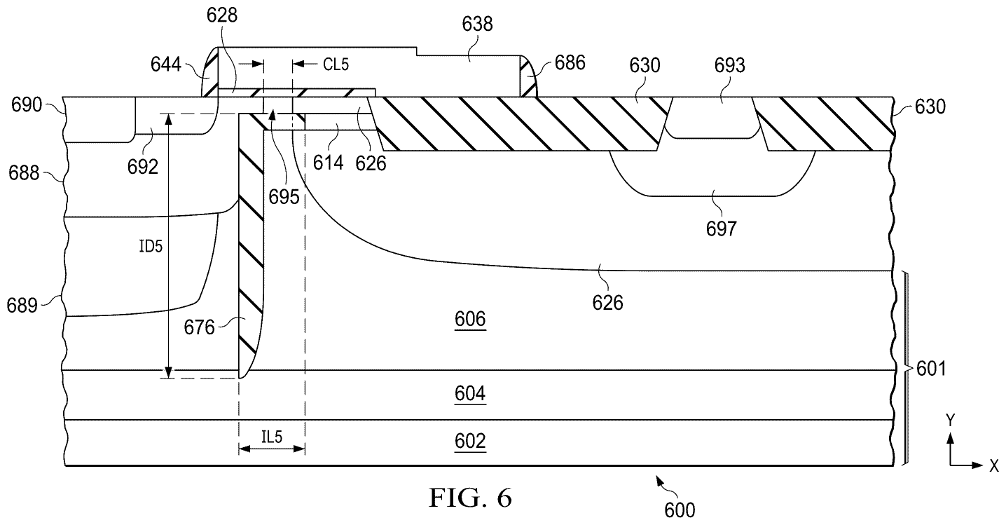

Referring now to FIG. 6, a diagrammatic cross-sectional view of a device 600 is illustrated, according to various aspects of the present disclosure. Device 600 may be fabricated using method 100 and/or method 300 as illustrated in FIG. 1 and FIG. 3, respectively. In various examples, device 600 may be a laterally diffused metal-oxide-semiconductor (LDMOS) field-effect-transistor (FET). As such, device 600 includes similar components as device 400 and device 500, including a substrate 601, a first p-type semiconductor layer 602, a n-type buried layer 604, a second p-type semiconductor layer 606, a first semiconductor material layer 614, a doped region 626, a gate dielectric 628, a gate electrode 638, a nitride spacer 644, an dielectric isolation structure 676, a gate spacer 686, a body diffusion region 688, a body region 690, a source region 692, a drain region 693, a first deep well 689, a second deep well 697, a thin channel region 695, a channel length CL5, source/drain contacts, and a gate contact, descriptions of which will not be repeated below.

Device 600 further includes shallow trench isolation (STI) structures 630. A first STI structure 630 may extend from first semiconductor material layer 614 to drain region 693 and under (e.g., in the negative y-direction) gate dielectric 628. In various examples STI structures 630 may be formed by forming a mask layer (e.g., silicon nitride) over substrate 601. Portions of the mask layer are removed exposing substrate 601. One or more trenches may be formed into substrate 601. A dielectric material is formed in the trenches to form STI structures 630.

As illustrated in FIG. 6, device 600 has a thin channel region 695 (e.g. a nanosheet channel region) defined in part by dielectric isolation structure 676. As shown, dielectric isolation structure 676 has a lateral isolation length IL5 extending in the direction of the transistor's channel length CL5 and a vertical isolation depth ID5 extending deeper into the substrate (e.g., along the y-axis). Specifically, lateral isolation length IL5 of dielectric isolation structure 676 extends from body diffusion region 688 through second p-type semiconductor layer 606 and into drift region 526, where the dielectric isolation structure 676 interfaces with first semiconductor material layer 614. Similar to devices 400′ and/or 400″ where the dielectric isolation structures extend into the drift region, the additional isolation provided by dielectric isolation structure 676 tends to further reduce the short channel effects and improve the gate control of device 600.

As discussed above, dielectric isolation structure 676 has a vertical isolation depth ID5 (e.g., along the y-axis). The vertical isolation depth ID5 of dielectric isolation structure 676 extends from body diffusion region 688, through second p-type semiconductor layer 606, and into n-type buried layer 604. In various examples, dielectric isolation structure 676 may extend into n-type buried layer 604 due to device 600 being designed to have a higher applied voltage at drain region 693 than either device 400 or device 500. In various examples, the depth of dielectric isolation structure 676 may be made deeper when the transistor is a higher voltage transistor (e.g. applied voltage to the drain is higher) and may be made shallower when the transistor is a lower voltage transistor (e.g. the supplied voltage to the drain is lower). Accordingly, the vertical isolation depth of dielectric isolation structure 676 may be modified to improve the gate control of device 600.

Accordingly, the methods and structures disclosed herein provide a thin channel region (e.g. nanosheet channel region) that is partially defined by a dielectric isolation structure disposed under the thin channel region. Using the methods and structures disclosed herein the semiconductor device is able to have, in various examples, a thin channel region (such as a nanosheet film) having a reduced doping concentration than would otherwise be used in such scaled down devices as an LDMOS FET. The relatively reduced doping concentration provides the benefits of increased channel mobility and/or reduce channel resistivity.

Finally, it should be understood that any of the above-described concepts can be used alone or in combination with any or all of the other above-described concepts. Although various examples have been disclosed and described, those of skill in this art would recognize that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A method, comprising:
receiving a semiconductor substrate having a first semiconductor material layer and a different second semiconductor material layer disposed on the first semiconductor material layer;
forming a drift region overlapping the first semiconductor material layer, the drift region doped to a first conductivity type;
forming a field relief insulator over the drift region;
forming a gate electrode layer over the field relief insulator;
removing a first portion of the second semiconductor material layer to form a trench that exposes a first portion of the first semiconductor material layer;
removing the exposed first portion of the first semiconductor material layer to extend the trench under the gate electrode layer toward the drift region, wherein a second portion of the second semiconductor material layer is exposed in the extended trench; and
forming a dielectric isolation structure in the extended trench, the dielectric isolation structure touching the second portion of the second semiconductor material layer.

2. The method of claim 1, wherein the extended trench is positioned within the drift region; and
wherein the dielectric isolation structure further interfaces with a portion of the drift region.

3. The method of claim 1, wherein the removing of the first portion of the second semiconductor material layer to form the trench that exposes the first portion of the first semiconductor material layer further includes removing a portion of the semiconductor substrate from under the first portion of the first semiconductor material layer such that a bottom surface of the first portion of the first semiconductor material layer is exposed in the trench, the bottom surface of the first portion of the first semiconductor material layer facing away from the gate electrode layer.

4. The method of claim 1, further comprising forming a third semiconductor material layer within the trench and touching the dielectric isolation structure.

5. The method of claim 4, further comprising forming a first source/drain region in the third semiconductor material layer, the first source/drain region doped to the first conductivity type; and
forming a second source/drain region in the drift region, the second source/drain region doped to the first conductivity type.

6. The method of claim 1, further comprising forming a first spacer feature along a sidewall surface of the field relief insulator, and
wherein the forming of the gate electrode layer on the field relief insulator includes forming the gate electrode layer on the first spacer feature.

7. The method of claim 6, further comprising forming a first dielectric material layer on the gate electrode layer, and
wherein the removing of the first portion of the second semiconductor material layer to form the trench includes:
patterning the first dielectric material layer to from a second spacer feature on a sidewall of the gate electrode layer, wherein the patterning of the first dielectric material layer includes removing a second portion of the first semiconductor material layer to expose a sidewall of the first semiconductor material layer;
forming a third spacer feature on the second spacer feature and the sidewall of the first semiconductor material layer; and
performing an etching process to remove a portion of the semiconductor substrate from under the first portion of the first semiconductor material layer.

8. The method of claim 7, wherein the forming the dielectric isolation structure further includes removing the third spacer feature.

9. The method of claim 1, wherein the forming the field relief insulator includes forming a local oxidation of silicon (LOCOS) layer having a tapered profiles at its lateral edges.

10. A method, comprising:
forming a first semiconductor material layer on a substrate;
forming a second semiconductor material layer on the first semiconductor material layer, the second semiconductor material layer having a different material composition than the first semiconductor material layer;
forming a gate structure over the second semiconductor material layer;
forming a trench through the first semiconductor material layer and the second semiconductor material layer adjacent the gate structure to expose a first portion of the substrate;
removing the first portion of the substrate through the trench to expose a first portion of the first semiconductor material layer;
removing the exposed first portion of the first semiconductor material layer, thereby exposing a first portion of the second semiconductor material layer and a second portion of the first semiconductor material layer; and
forming a dielectric isolation structure directly on the first portion of the second semiconductor material layer and the second portion of the first semiconductor material layer.

11. The method of claim 10, further comprising forming a doped well region extending through the first semiconductor material layer into the substrate, and
wherein the removing of the exposed first portion of the first semiconductor material layer includes removing a portion of the doped well region formed in the first portion of the first semiconductor material layer.

12. The method of claim 10, wherein the first portion of the second semiconductor material layer has a bottom surface facing the substrate that is exposed after the removing the exposed first portion of the first semiconductor material layer.

13. The method of claim 10, further comprising forming a dielectric spacer on a sidewall of the first semiconductor material layer, a sidewall of the second semiconductor material layer, and the first portion of the substrate and then removing the first portion of the substrate.

14. The method of claim 13, wherein forming the dielectric spacer includes removing the first portion of the substrate and removing a portion of a spacer dielectric layer formed over the gate structure and touching the first portion of the substrate.

15. The method of claim 14, wherein the forming of the dielectric isolation structure includes:
forming an isolation dielectric layer extending from over a top surface of the gate structure to the first portion of the second semiconductor material layer and the second portion of the first semiconductor material layer; and
removing the isolation dielectric layer from within the trench thereby forming the dielectric isolation structure.

16. A device comprising:
a first semiconductor material layer disposed over a substrate;
a second semiconductor material layer disposed on the first semiconductor material layer;
a drift region extending through the first semiconductor material layer into the substrate, the drift region doped to a first conductivity type;
a body region disposed in the second semiconductor material layer and the substrate, the body region doped to a second conductivity type that is opposite the first conductivity type;
a source region extending into the body region and doped to the first conductivity type;
a drain region extending into the drift region and doped to the first conductivity type;
a gate structure including a gate electrode layer spaced apart from the second semiconductor material layer by a gate dielectric layer; and
a dielectric isolation structure under the body region and having a first portion extending into the substrate and a second portion extending beyond an edge of the first portion toward the drain region between the gate structure and the substrate and abutting the first semiconductor material layer.

17. The device of claim 16, wherein a portion of the second semiconductor material layer extends from the gate dielectric layer to the dielectric isolation structure.

18. The device of claim 16, wherein the dielectric isolation structure extends into the drift region.

19. The device of claim 16, wherein the substrate includes a doped buried layer extending under the body region, the first semiconductor material layer, the second semiconductor material layer, and the drift region, the doped buried layer doped to the first conductivity type, and
wherein the dielectric isolation structure further extends within the substrate into the doped buried layer.

20. The device of claim 16, further comprising a field relief insulator disposed on the gate dielectric layer, and
wherein the dielectric isolation structure extends continuously from under the body region to under the field relief insulator.
